(19) United States
(12) Patent Application Publication
(10) Pub. No.: US 2025/0357040 A1
(43) Pub. Date: Nov. 20, 2025

(54) TRANSFORMER CHIP

(71) Applicant: ROHM CO., LTD., Kyoto (JP)

(72) Inventor: Kosei OSADA, Kyoto-shi (JP)

(73) Assignee: ROHM CO., LTD., Kyoto (JP)

(21) Appl. No.: 19/286,504

(22) Filed: Jul. 31, 2025

Related U.S. Application Data
(63) Continuation of application No. PCT/JP2024/002553, filed on Jan. 29, 2024.

(30) Foreign Application Priority Data
Feb. 9, 2023 (JP) 2023-018609

(51) Int. Cl. H01F 27/28; H01F 27/29

(52) U.S. Cl. CPC H01F 27/2804; H01F 27/292; H01F 2027/2809

(57) ABSTRACT

A transformer chip includes: an insulating layer having an upper surface and a lower surface at opposite sides in a thickness-wise direction; a first coil located closer to the upper surface than to the lower surface in the insulating layer; a second coil facing the first coil and located closer to the lower surface than to the upper surface in the insulating layer; and a first pad formed on the upper surface and electrically connected to the first coil. As viewed in the thickness-wise direction, the first pad includes a first extension located in an inner region surrounded by the first coil, the first extension extending toward the first coil beyond a position 5 μm inward of an inner circumferential edge of the first coil.

### CROSS-REFERENCE TO RELATED APPLICATIONS

This application is a continuation of, and claims the benefit of priority from International Application No. PCT/JP2024/002553, filed on Jan. 29, 2024, which claims the benefit of priority from Japanese Patent Application No. 2023-018609, filed on Feb. 9, 2023, the entire contents of each of which are incorporated herein by reference.

### BACKGROUND

### 1. Field

The following description relates to a transformer chip.

### 2. Description of Related Art

An insulated gate driver is an example of a gate driver that applies gate voltage to a gate of a switching element, such as a transistor. Patent Literature 1 describes an example of an electronic component that includes a transformer chip having a primary-side coil and a secondary coil.
Patent Literature 1: Japanese Laid-Open Patent Publication No. 2018-78169

### BRIEF DESCRIPTION OF THE DRAWINGS

FIG. 1 is a schematic circuit diagram showing the configuration of a signal transmission device in accordance with an embodiment.

FIG. 2 is a schematic plan view showing the configuration of the signal transmission device shown in FIG. 1.

FIG. 3 is a schematic cross-sectional view showing the configuration of the signal transmission device shown in FIG. 2.

FIG. 4 is a schematic perspective view showing a transformer chip of the signal transmission device shown in FIG. 3.

FIG. 5 is a schematic plan view of the transformer chip shown in FIG. 4.

FIG. 6 is a schematic plan view showing a second coil of the transformer chip shown in FIG. 4.

FIG. 7 is a schematic plan view showing a first coil of the transformer chip shown in FIG. 4.

FIG. 8 is a cross-sectional view taken along line 8-8 shown in FIG. 5.

FIG. 9 is a cross-sectional view taken along line 9-9 shown in FIG. 5.

FIG. 10 is a plan view enlarging part of the first coil shown in FIG. 6.

FIG. 11 is a cross-sectional view taken along line 11-11 shown in FIG. 10.

FIG. 12 is a schematic cross-sectional view illustrating simulated electric field intensity in the transformer chip shown in FIG. 4.

FIG. 13 is a schematic cross-sectional view illustrating simulated electric field intensity in a transformer chip of a comparative example.

FIG. 14 is a schematic plan view showing a transformer chip of a modified example.

FIG. 15 is a plan view enlarging part of FIG. 14.

FIG. 16 is a schematic plan view showing part of a transformer chip of a modified example.

FIG. 17 is a schematic cross-sectional view showing a transformer chip of a modified example.

FIG. 18 is a schematic cross-sectional view showing a transformer chip of a modified example.

FIG. 19 is a schematic cross-sectional view showing a transformer chip of a modified example.

FIG. 20 is a schematic plan view showing part of a transformer chip of a modified example.

FIG. 21 is a schematic cross-sectional view showing part of the transformer chip shown in FIG. 20.

FIG. 22 is a schematic plan view showing part of a transformer chip of a modified example.

FIG. 23 is a schematic cross-sectional view showing part of the transformer chip shown in FIG. 22.

FIG. 24 is a schematic plan view showing a transformer chip of a modified example.

FIG. 25 is a schematic plan view showing a transformer chip of a modified example.

FIG. 26 is a schematic plan view showing a transformer chip of a modified example.

FIG. 27 is a schematic circuit diagram showing the configuration of a signal transmission device of a modified example.

FIG. 28 is a schematic plan view showing the configuration of the signal transmitting device shown in FIG. 27.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Some embodiments of a signal transmission device and a transformer chip according to the present disclosure will now be described with reference to the drawings. Elements in the drawings are illustrated for simplicity and clarity and have not necessarily been drawn to scale. To facilitate understanding, hatching lines may not be shown in the cross-sectional drawings. The accompanying drawings merely illustrate exemplary embodiments of the present disclosure and are not intended to limit the present disclosure. Terms such as “first”, “second”, or “third” in this disclosure are used to distinguish subjects and are not used for ordinal purposes.

This detailed description provides exemplary embodiments of methods, apparatuses, and/or systems in accordance with the present disclosure. Further, this detailed description is illustrative and is not intended to limit embodiments of the present disclosure or the application and use of the embodiments.

In this specification, the phrase “at least one of” as used in this disclosure means “one or more” of a desired choice. As one example, the phrase “at least one of” as used in this disclosure means “only one single choice” or “both of two choices” if the number of its choices is two. As another example, the phrase “at least one of” as used in this disclosure means “only one single choice” or “any combination of two or more choices” if the number of its choices is three or more.

### Embodiment

### Overall Configuration of Signal Transmission Device

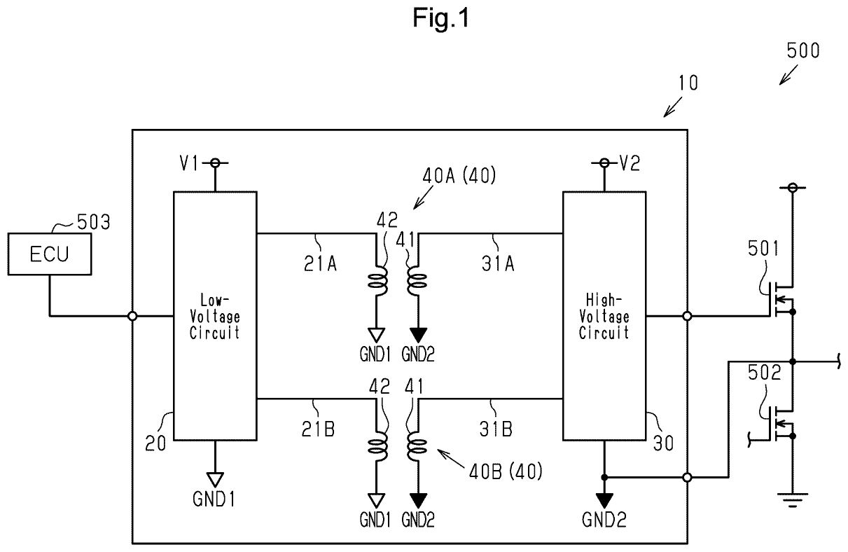

The overall configuration of a signal transmission device 10 in accordance with an embodiment will now be described with reference to FIGS. 1 to 3.

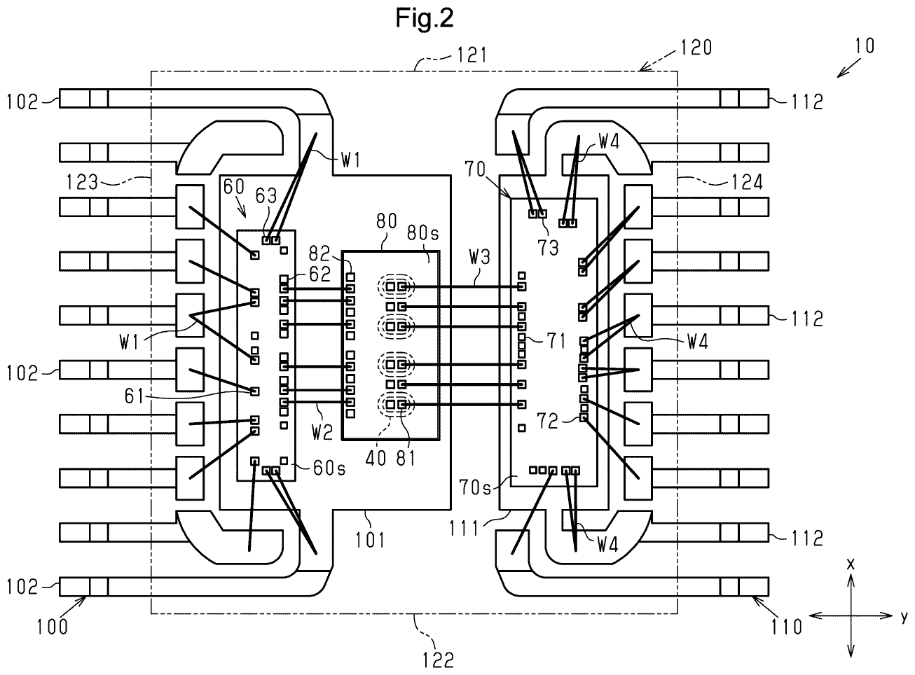

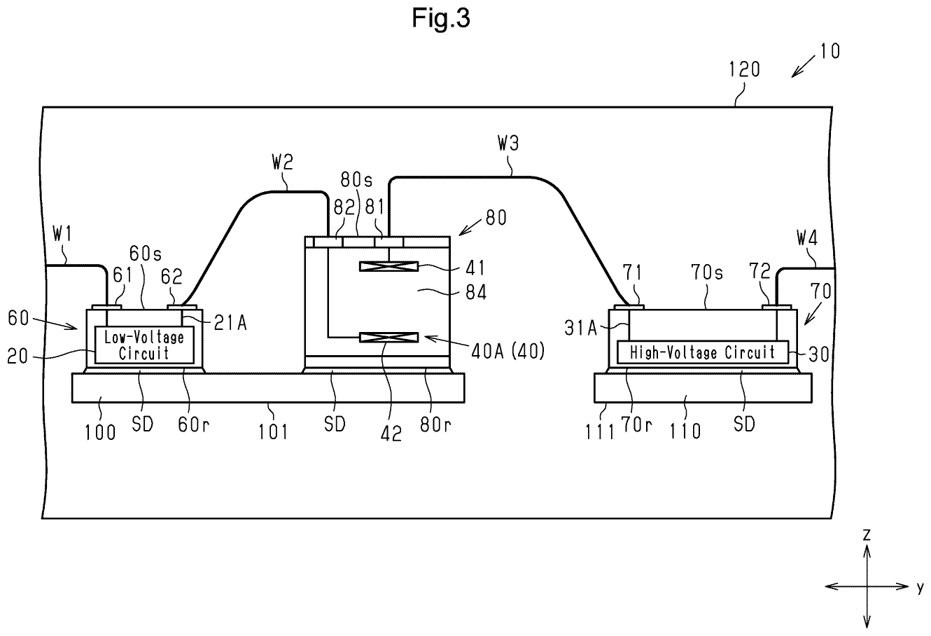

FIG. 1 schematically shows the circuit configuration of the signal transmission device 10 in accordance with the embodiment. FIG. 2 schematically shows an example of the internal configuration (planar structure) of the signal transmission device 10. FIG. 3 schematically shows an example of part of the internal configuration (cross-sectional structure) of the signal transmission device 10. To simplify illustration, FIG. 3 does not show hatching lines.

As shown in FIG. 1, the signal transmission device 10 may be used in an inverter device 500. The inverter device 500 includes a control circuit (electronic control unit, ECU) 503, the signal transmission device 10, and switching elements 501 and 502. The signal transmission device 10 is used as a gate driver that drives the switching element 501 with the control circuit 503. FIG. 1 shows the signal transmission device 10 that drives the switching element 501.

The switching element 501 is a high-side switching element connected to a drive power supply, for example. The switching element 502 is a low-side switching element. Examples of the switching elements 501 and 502 include transistors, such as a Si metal-oxide-semiconductor field-effect transistor (Si MOSFET), a SiC MOSFET, an insulated gate bipolar transistor (IGBT), or the like.

The signal transmission device 10 applies a drive voltage signal to a control terminal of the switching element 501. In the example described hereinafter, the switching elements 501 and 502 are SiC MOSFETs. The signal transmission device 10 is provided for each of the switching elements 501 and 502, and the switching elements 501 and 502 are driven separately.

The signal transmission device 10 includes a low-voltage circuit 20 to which a first voltage V1 is applied, a high-voltage circuit 30 to which a second voltage V2 that is higher than the first voltage V1 is applied, and a transformer 40 disposed between the low-voltage circuit 20 and the high-voltage circuit 30. That is, the transformer 40 connects the low-voltage circuit 20 and the high-voltage circuit 30. The first voltage V1 and the second voltage V2 are DC voltages.

The signal transmission device 10 of the present embodiment is configured so that, in response to a control signal from the control circuit 503, the low-voltage circuit 20 transmits a signal to the high-voltage circuit 30 via the transformer 40, and the high-voltage circuit 30 outputs a drive voltage signal.

The signal transmitted from the low-voltage circuit 20 toward the high-voltage circuit 30, or the signal output from the low-voltage circuit 20, includes, for example, a signal for driving the switching element 501, such as a set signal (SET) and a reset signal (RESET). The set signal is a signal that transmits a rising edge of a control signal of the control circuit 503, and the reset signal is a signal that transmits a falling edge of the control signal of the control circuit 503. In other words, the set signal and the reset signal are signals for generating a drive voltage signal for the switching element 501. The set signal and the reset signal correspond to a first signal.

More specifically, the low-voltage circuit 20 is configured to be actuated when the first voltage V1 is applied to the low-voltage circuit 20. The low-voltage circuit 20 is electrically connected to the control circuit 503 and generates a set signal and a reset signal based on a control signal received from the control circuit 503. For example, the low-voltage circuit 20 generates a set signal in response to a rising edge of the control signal, and generates a reset signal in response to a falling edge of the control signal. The low-voltage circuit 20 transmits the generated set signal and reset signal toward the high-voltage circuit 30.

The high-voltage circuit 30 is configured to be actuated when the second voltage V2 is applied to the high-voltage circuit 30. The high-voltage circuit 30 is electrically connected to a gate of the switching element 501. Based on the set signal and the reset signal received from the low-voltage circuit 20, the high-voltage circuit 30 generates a drive voltage signal for driving the switching element 501, and applies the drive voltage signal to the gate of the switching element 501. In other words, the high-voltage circuit 30 generates a drive voltage signal applied to the gate of the switching element 501 in response to the first signal output from the low-voltage circuit 20. More specifically, the high-voltage circuit 30 generates a drive voltage signal for activating the switching element 501 based on the set signal, and applies the drive voltage signal to the gate of the switching element 501. Further, the high-voltage circuit 30 generates a drive voltage signal for deactivating the switching element 501 based on the reset signal, and applies the drive voltage signal to the gate of the switching element 501. In this manner, the signal transmission device 10 controls activation and deactivation of the switching element 501.

The high-voltage circuit 30 includes, for example, an RS type flip-flop circuit, which receives a set signal and a reset signal, and a driver, which generates a drive voltage signal in response to an output signal of the RS type flip-flop circuit. The specific circuit configuration of the high-voltage circuit 30 may be changed.

In the signal transmission device 10 of the present embodiment, the transformer 40 insulates the low-voltage circuit 20 from the high-voltage circuit 30. More specifically, the transformer 40 restricts transmission of DC voltage between the low-voltage circuit 20 and the high-voltage circuit 30 while permitting transmission of various signals, such as the set signal and the reset signal.

Therefore, a state in which the low-voltage circuit 20 and the high-voltage circuit 30 are insulated from each other refers to a state in which transmission of DC voltage is restricted between the low-voltage circuit 20 and the high-voltage circuit 30 and transmission of a signal is permitted between the low-voltage circuit 20 and the high-voltage circuit 30.

The signal transmission device 10 has a dielectric breakdown voltage of, for example, 2500 Vrms or greater and 7500 Vrms or less. The dielectric breakdown voltage of the signal transmission device 10 of the present embodiment is approximately 5000 Vrms. The dielectric breakdown voltage of the signal transmission device 10 is not limited to any specific numerical value.

In the present embodiment, ground GND1 of the low-voltage circuit 20 and ground GND2 of the high-voltage circuit 30 are arranged independent from each other. Hereinafter, the potential of the ground GND1 of the low-voltage circuit 20 will be referred to as the first reference potential, and the potential of the ground GND2 of the high-voltage circuit 30 will be referred to as the second reference potential. In this case, the first voltage V1 is a voltage from the first reference potential, and the second voltage V2 is a voltage from the second reference potential. The first voltage V1 is, for example, 4.5 V or greater and 5.5 V or less. The second voltage V2 is, for example, 9 V or greater and 24 V or less.

### Transformer

The transformers 40 will now be described in detail.

The signal transmission device 10 of the present embodiment includes two transformers 40 corresponding to two signals transmitted from the low-voltage circuit 20 toward the high-voltage circuit 30. To facilitate understanding, one of the two transformers 40 will be referred to as the transformer 40A, and the other one of the two transformers 40 will be referred to as the transformer 40B. In an example, the transformer 40A transmits a set signal. The transformer 40B transmits a reset signal. In an example, the set signal and the reset signal may be for a reception circuit included in the high-voltage circuit 30.

The signal transmission device 10 includes a low-voltage signal line 21A, which connects the low-voltage circuit 20 to the transformer 40A, and a low-voltage signal line 21B, which connects the low-voltage circuit 20 to the transformer 40B. Accordingly, the low-voltage signal line 21A transmits a set signal from the low-voltage circuit 20 to the transformer 40A. The low-voltage signal line 21B transmits a reset signal from the low-voltage circuit 20 to the transformer 40B.

The signal transmission device 10 includes a high-voltage signal line 31A, which connects the transformer 40A and the high-voltage circuit 30, and a high-voltage signal line 31B, which connects the transformer 40B and the high-voltage circuit 30. Accordingly, the high-voltage signal line 31A transmits a set signal from the transformer 40A to the high-voltage circuit 30. The high-voltage signal line 31B transmits a reset signal from the transformer 40B to the high-voltage circuit 30.

The transformer 40A transmits a set signal from the low-voltage circuit 20 to the high-voltage circuit 30 while electrically insulating the low-voltage circuit 20 from the high-voltage circuit 30. The transformer 40B transmits a reset signal from the low-voltage circuit 20 to the high-voltage circuit 30 while electrically insulating the low-voltage circuit 20 from the high-voltage circuit 30.

The transformers 40A and 40B each include a first coil 41 and a second coil 42. The first coil 41 and the second coil 42 are electrically insulated from each other and are configured to be magnetically coupled to each other.

The second coil 42 of the transformer 40A is connected to the low-voltage circuit 20 by the low-voltage signal line 21A and to the ground GND1 of the low-voltage circuit 20. More specifically, the second coil 42 of the transformer 40A has a first end electrically connected to the low-voltage circuit 20, and a second end electrically connected to the ground GND1 of the low-voltage circuit 20. The second coil 42 of the transformer 40B is connected to the low-voltage circuit 20 by the low-voltage signal line 21B and to the ground GND1 of the low-voltage circuit 20. More specifically, the second coil 42 of the transformer 40B has a first end electrically connected to the low-voltage circuit 20, and a second end electrically connected to the ground GND1 of the low-voltage circuit 20. In this manner, the potential at the second end of the second coil 42 in each of the transformers 40A and 40B corresponds to the first reference potential. The first reference potential is, for example, 0 V.

The first coil 41 of the transformer 40A is connected to the high-voltage circuit 30 by the high-voltage signal line 31A and to the ground GND2 of the high-voltage circuit 30. More specifically, the first coil 41 of the transformer 40A has a first end electrically connected to the high-voltage circuit 30, and a second end electrically connected to the ground GND2 of the high-voltage circuit 30. The first coil 41 of the transformer 40B is connected to the high-voltage circuit 30 by the high-voltage signal line 31B and to the ground GND2 of the high-voltage circuit 30. More specifically, the first coil 41 of the transformer 40B has a first end electrically connected to the high-voltage circuit 30, and a second end electrically connected to the ground GND2 of the high-voltage circuit 30. In this manner, the potential at the second end of the first coil 41 in each of the transformers 40A and 40B corresponds to the second reference potential. The ground GND2 of the high-voltage circuit 30 is connected to a source of the switching element 501. Accordingly, the second reference potential varies when the inverter device 500 is driven and may become 600 V or greater, for example.

FIG. 2 is an example of a plan view showing the internal configuration of the signal transmission device 10. FIG. 3 is an example of a cross-sectional view showing the internal configuration of the signal transmission device 10. In FIG. 1, the circuit configuration of the signal transmission device 10 is simplified. Thus, the number of external terminals of the signal transmission device 10 in FIG. 2 is greater than the number of external terminals of the signal transmission device 10 in FIG. 1. The number of external terminals of the signal transmission device 10 refers to the number of external electrodes that allow for connection between the signal transmission device 10 and an electronic component external to the signal transmission device 10, such as the control circuit 503, the switching element 501 (refer to FIG. 1), or the like. Also, in the signal transmission device 10 shown in FIG. 2, the number of signal lines (number of wires W1 to W4, described later) for transmitting a signal from the low-voltage circuit 20 to the high-voltage circuit 30 is greater than the number of signal lines in the signal transmission device 10 shown in FIG. 1.

As shown in FIG. 2, the signal transmission device 10 is a semiconductor device, in which multiple semiconductor chips are packaged, and is mounted on a circuit substrate of the inverter device 500, for example. The switching elements 501 and 502 are mounted on another mount substrate that differs from the circuit substrate. The mount substrate is attached to a cooling device.

The package type of the signal transmission device 10 is small outline (SO). In the present embodiment, the signal transmission device 10 is a small outline package (SOP). For example, a low-voltage circuit chip 60, a high-voltage circuit chip 70, and a transformer chip 80 are semiconductor chips. The low-voltage circuit chip 60 is mounted on a low-voltage lead frame 100. The high-voltage circuit chip 70 is mounted on a high-voltage lead frame 110. The chips 60, 70, and 80 and part of the lead frames 100 and 110 are encapsulated by a mold resin 120. In the present embodiment, the transformer chip 80 and the mold resin 120 correspond to an insulation module that insulates the low-voltage circuit 20 from the high-voltage circuit 30. In FIG. 2, the mold resin 120 is indicated by double-dashed lines such that the internal structure of the signal transmission device 10 can be shown. The package type of the signal transmission device 10 may be changed.

The mold resin 120 is formed from an electrically insulative material. An example of such resin includes a black epoxy resin. The mold resin 120 has the shape of a rectangular plate having a thickness-wise direction that is parallel to the z-direction. The mold resin 120 includes four resin side surfaces 121 to 124. More specifically, the mold resin 120 includes the resin side surfaces 121 and 122 serving as two end surfaces in the x-direction, and the resin side surfaces 123 and 124 serving as two end surfaces in the y-direction. The x-direction and the y-direction are orthogonal to the z-direction. The x-direction and the y-direction are orthogonal to each other. The x-direction corresponds to a first direction. The y-direction corresponds to a second direction. In the description hereafter, a plan view means a view taken in the z-direction.

The low-voltage lead frame 100 and the high-voltage lead frame 110 are conductors. In the present embodiment, the low-voltage lead frame 100 and the high-voltage lead frame 110 are formed from a material containing copper (Cu), iron (Fe), or the like. The lead frames 100 and 110 extend from the inside to the outside of the mold resin 120.

The low-voltage lead frame 100 includes a low-voltage die pad 101 arranged in the mold resin 120, and low-voltage leads 102 extending from the inside to the outside of the mold resin 120. The low-voltage leads 102 form the external terminals for electrical connection with an external electronic device, such as the control circuit 503 (refer to FIG. 1).

In the present embodiment, both the low-voltage circuit chip 60 and the transformer chip 80 are mounted on the low-voltage die pad 101. In plan view, the low-voltage die pad 101 is arranged so that its central part in the y-direction is located closer to the resin side surface 123 than the central part of the mold resin 120 is in the y-direction. In the present embodiment, the low-voltage die pad 101 is not exposed from the mold resin 120. In plan view, the low-voltage die pad 101 has a rectangular shape, in which long sides extend in the x-direction and short sides extend in the y-direction.

The low-voltage leads 102 are spaced apart from one another in the x-direction. The two outermost low-voltage leads 102 in the x-direction are integrated with the low-voltage die pad 101. Each of the low-voltage leads 102 partially projects out of the mold resin 120 from the resin side surface 123.

The high-voltage lead frame 110 includes a high-voltage die pad 111 arranged in the mold resin 120, and high-voltage leads 112 extending from the inside to the outside of the mold resin 120. The high-voltage leads 112 form the external terminals for electrical connection with an external electronic device, such as the gate of the switching element 501 (refer to FIG. 1).

The high-voltage circuit chip 70 is mounted on the high-voltage die pad 111. In plan view, the high-voltage die pad 111 is located closer to the resin side surface 124 than the low-voltage die pad 101 is in the y-direction. In the present embodiment, the high-voltage die pad 111 is not exposed from the mold resin 120. In plan view, the high-voltage die pad 111 has a rectangular shape, in which long sides extend in the x-direction and short sides extend in the y-direction.

The low-voltage die pad 101 and the high-voltage die pad 111 are spaced apart from each other in the y-direction. Accordingly, the y-direction may also be referred to as the arrangement direction of the two die pads 101 and 111.

The dimensions of the low-voltage die pad 101 and the high-voltage die pad 111 in the y-direction are determined in accordance with the size and quantity of the mounted semiconductor chips. In the present embodiment, the low-voltage circuit chip 60 and the transformer chip 80 are mounted on the low-voltage die pad 101, and the high-voltage circuit chip 70 is mounted on the high-voltage die pad 111. Accordingly, the low-voltage die pad 101 is larger than the high-voltage die pad 111 in the y-direction.

The high-voltage leads 112 are spaced apart from one another in the x-direction. Two of the high-voltage leads 112 are integrated with the high-voltage die pad 111. Each of the high-voltage leads 112 partially projects out of the mold resin 120 from the resin side surface 124.

In the present embodiment, the number of high-voltage leads 112 is the same as the number of low-voltage leads 102. As apparent from FIG. 2, the low-voltage leads 102 and the high-voltage leads 112 are arranged next to one another in a direction (x-direction) orthogonal to the arrangement direction (y-direction) of the low-voltage die pad 101 and the high-voltage die pad 111. The number of high-voltage leads 112 and the number of low-voltage leads 102 may be changed.

In the present embodiment, the low-voltage die pad 101 is supported by the two low-voltage leads 102 integrated with the low-voltage die pad 101. The high-voltage die pad 111 is supported by the two high-voltage leads 112 integrated with the high-voltage die pad 111. Accordingly, the die pads 101 and 111 do not include suspension leads exposed from the resin side surfaces 121 and 122. This allows the low-voltage lead frame 100 and the high-voltage lead frame 110 to be spaced apart by a relatively long insulating distance.

The low-voltage circuit chip 60, the high-voltage circuit chip 70, and the transformer chip 80 are spaced apart from one another in the y-direction. The low-voltage circuit chip 60, the transformer chip 80, and the high-voltage circuit chip 70 are arranged in this order from the low-voltage leads 102 to the high-voltage leads 112 in the y-direction.

The low-voltage circuit chip 60 includes the low-voltage circuit 20 shown in FIG. 1. In plan view, the low-voltage circuit chip 60 has a rectangular shape with short sides and long sides. In plan view, the low-voltage circuit chip 60 is mounted on the low-voltage die pad 101 such that the long sides extend in the x-direction and the short sides extend in the y-direction. As shown in FIG. 3, the low-voltage circuit chip 60 has a chip main surface 60s and a chip back surface 60r at opposite sides in the z-direction. The chip back surface 60r of the low-voltage circuit chip 60 is bonded to the low-voltage die pad 101 by a conductive bonding material SD. The conductive bonding material SD is solder, silver (Ag) paste, or the like.

First electrode pads 61, second electrode pads 62, and third electrode pads 63 are formed on the chip main surface 60s of the low-voltage circuit chip 60. The electrode pads 61 to 63 are electrically connected to the low-voltage circuit 20.

The first electrode pads 61 are disposed on the chip main surface 60s at a portion located closer to the low-voltage leads 102 than the center of the chip main surface 60s in the y-direction is. The first electrode pads 61 are arranged next to one another in the x-direction. The second electrode pads 62 are disposed at one of two opposite ends of the chip main surface 60s in the y-direction that is located relatively close to the transformer chip 80. The second electrode pads 62 are arranged next to one another in the x-direction. The third electrode pads 63 are disposed at two opposite end portions of the chip main surface 60s in the x-direction.

The high-voltage circuit chip 70 includes the high-voltage circuit 30 shown in FIG. 1. In plan view, the high-voltage circuit chip 70 has a rectangular shape with short sides and long sides. In plan view, the high-voltage circuit chip 70 is mounted on the high-voltage die pad 111 such that the long sides extend in the x-direction and the short sides extend in the y-direction. As shown in FIG. 3, the high-voltage circuit chip 70 has a chip main surface 70s and a chip back surface 70r at opposite sides in the z-direction. The chip back surface 70r of the high-voltage circuit chip 70 is bonded to the high-voltage die pad 111 by the conductive bonding material SD.

First electrode pads 71, second electrode pads 72, and third electrode pads 73 are formed on the chip main surface 70s of the high-voltage circuit chip 70. The electrode pads 71 to 73 are electrically connected to the high-voltage circuit 30.

The first electrode pads 71 are disposed at one of two opposite end portions of the chip main surface 70s in the y-direction that is located relatively close to the transformer chip 80. The first electrode pads 71 are arranged next to one another in the x-direction. The second electrode pads 72 are disposed at one of two opposite end portions of the chip main surface 70s in the y-direction that is located relatively far from the transformer chip 80. In other words, the second electrode pads 72 are disposed at one of the two opposite end portions of the chip main surface 70s in the y-direction that is located relatively close to the high-voltage leads 112. The second electrode pads 72 are arranged next to one another in the x-direction. The third electrode pads 73 are disposed at two opposite end portions of the chip main surface 70s in the x-direction.

The transformer chip 80 includes the transformer 40 (40A, 40B) shown in FIG. 1. In plan view, the transformer chip 80 has a rectangular shape with short sides and long sides. In the present embodiment, in plan view, the transformer chip 80 is mounted on the low-voltage die pad 101 such that the long sides extend in the x-direction and the short sides extend in the y-direction.

The transformer chip 80 is arranged next to the low-voltage circuit chip 60 in the y-direction. The transformer chip 80 is located closer to the high-voltage circuit chip 70 than the low-voltage circuit chip 60 is. That is, the transformer chip 80 is located between the low-voltage circuit chip 60 and the high-voltage circuit chip 70 in the y-direction.

As shown in FIG. 3, the transformer chip 80 has a chip main surface 80s and a chip back surface 80r at opposite sides in the z-direction. The chip back surface 80r of the transformer chip 80 is bonded to the low-voltage die pad 101 by the conductive bonding material SD.

As shown in FIG. 2, first electrode pads 81 and second electrode pads 82 are formed on the chip main surface 80s of the transformer chip 80.

The second electrode pads 82 are, for example, disposed at one of two opposite end portions of the chip main surface 80s in the y-direction that is located relatively close to the low-voltage circuit chip 60. The second electrode pads 82 are arranged next to one another in the x-direction. The first electrode pads 81 are, for example, disposed near the center of the chip main surface 80s in the y-direction. The first electrode pads 81 are arranged next to one another in the x-direction.

As shown in FIG. 2, the lead frames 100 and 110 become closest to each other at the low-voltage die pad 101 and the high-voltage die pad 111. Accordingly, the low-voltage die pad 101 and the high-voltage die pad 111 need to be spaced apart from each other, such that the signal transmission device 10 has a predetermined dielectric breakdown voltage. Therefore, in plan view, the distance from the high-voltage circuit chip 70 to the transformer chip 80 is greater than the distance from the low-voltage circuit chip 60 to the transformer chip 80.

Wires W1 to W4 are connected to the low-voltage circuit chip 60, the transformer chip 80, and the high-voltage circuit chip 70. The wires W1 to W4 are bonding wires formed by a wire bonding device, and are formed from a conductor containing for example gold (Au), aluminum (Al), Cu, or the like.

The low-voltage circuit chip 60 is electrically connected to the low-voltage lead frame 100 by the wires W1. More specifically, the first electrode pads 61 and the third electrode pads 63 of the low-voltage circuit chip 60 are connected to the low-voltage leads 102 by the wires W1. The third electrode pads 63 of the low-voltage circuit chip 60 are connected to the two of the low-voltage leads 102 integrated with the low-voltage die pad 101 by the wires W1. In this manner, the low-voltage circuit 20 is electrically connected to the low-voltage leads 102 (external electrodes of the signal transmission device 10 for electrical connection with the control circuit 503). In the present embodiment, the two low-voltage leads 102 integrated with the low-voltage die pad 101 form the ground terminal, and the wires W1 electrically connect the low-voltage circuit 20 to the low-voltage die pad 101. Therefore, the low-voltage die pad 101 has the same potential as the ground GND1 of the low-voltage circuit 20.

The high-voltage circuit chip 70 is electrically connected to the high-voltage leads 112 of the high-voltage lead frame 110 by the wires W4. More specifically, the second electrode pads 72 and the third electrode pads 73 of the high-voltage circuit chip 70 are connected to the high-voltage leads 112 by the wires W4. In this manner, the high-voltage circuit 30 is electrically connected to the high-voltage leads 112 (external electrodes of the signal transmission device 10 for electrical connection with the switching element 501 or the like). In the present embodiment, the two high-voltage leads 112 integrated with the high-voltage die pad 111 form the ground terminal, and the wires W4 electrically connect the high-voltage circuit 30 to the high-voltage die pad 111. Therefore, the high-voltage die pad 111 has the same potential as the ground GND2 of the high-voltage circuit 30.

The transformer chip 80 is connected to the low-voltage circuit chip 60 by the wires W2. Also, the transformer chip 80 is connected to the high-voltage circuit chip 70 by the wires W3. More specifically, the second electrode pads 82 of the transformer chip 80 are connected to the second electrode pads 62 of the low-voltage circuit chip 60 by the wires W2. The first electrode pads 81 of the transformer chip 80 are connected to the first electrode pads 71 of the high-voltage circuit chip 70 by the wires W3.

The second coil 42 of both transformers 40A and 40B (refer to FIG. 1) are electrically connected to the ground GND1 of the low-voltage circuit 20 via the wires W2, the low-voltage circuit chip 60, and the like. The first coil 41 of both transformers 40A and 40B (refer to FIG. 1) are electrically connected to the ground GND2 of the high-voltage circuit 30 via the wires W3, the high-voltage circuit chip 70, and the like.

### Configuration of Transformer Chip

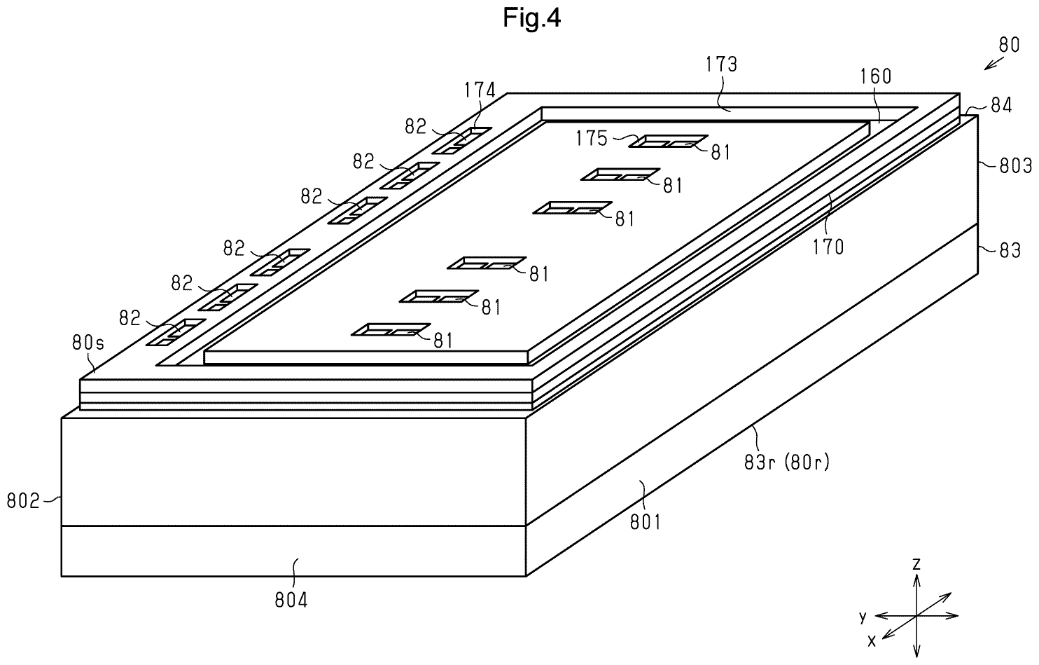

An example of the configuration of the transformer chip 80 will now be described with reference to FIGS. 4 to 11.

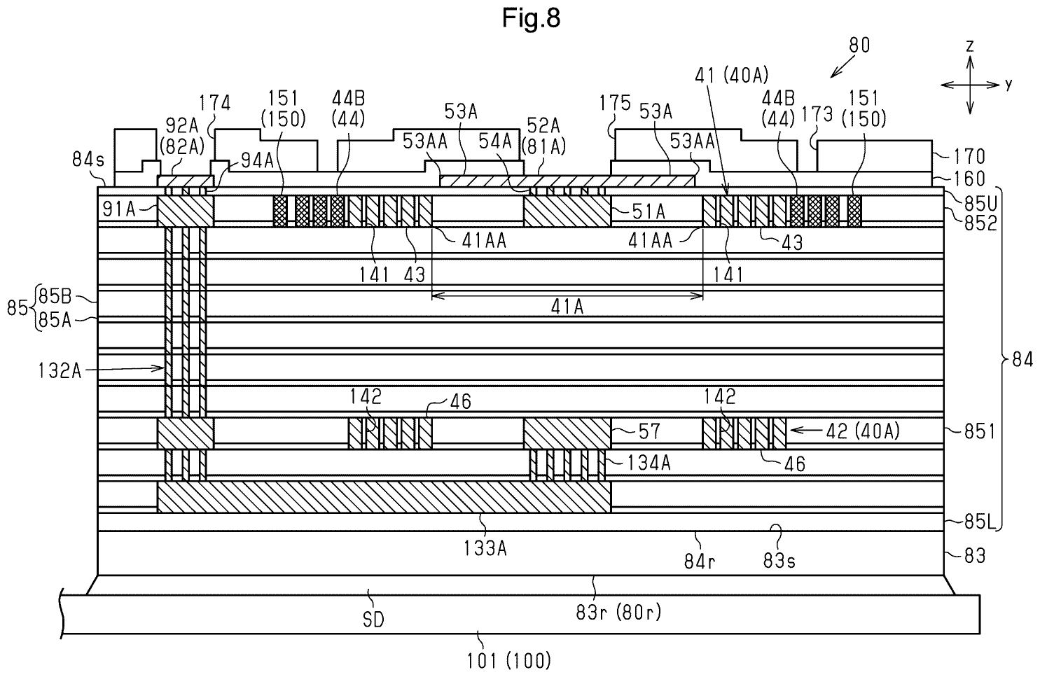

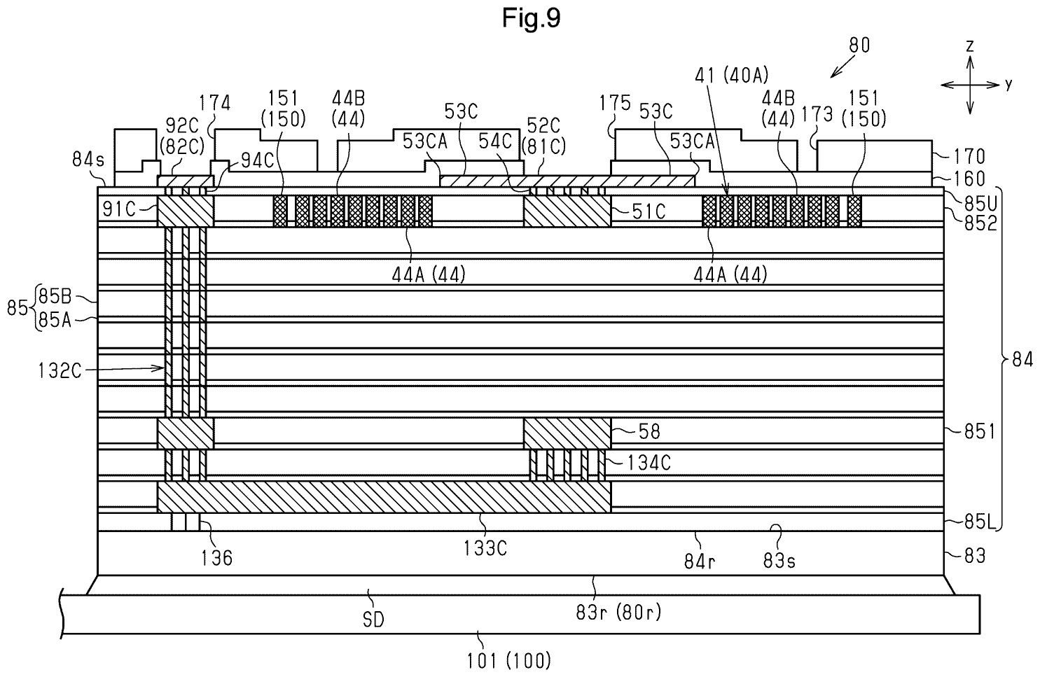

In the description hereafter, referring to FIGS. 8 and 9, the direction extending from the chip back surface 80r of the transformer chip 80 toward the chip main surface 80s will be referred to as the upward direction, and the direction extending from the chip main surface 80s toward the chip back surface 80r will be referred to as the downward direction.

FIG. 4 is a perspective view showing the external appearance of the transformer chip 80.

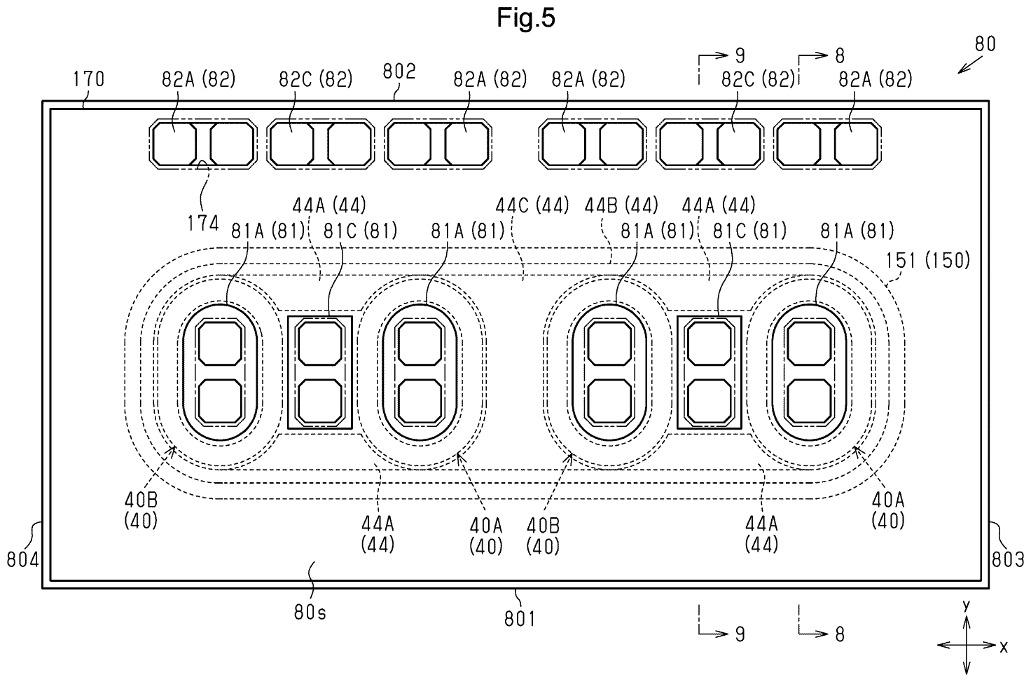

FIG. 5 is a plan view of the transformer chip 80. In FIG. 5, for illustrative purposes, a passivation film 160 is indicated by double-dashed lines, and the transformers 40A and 40B and stray dummy wiring 150, which will be described later, are indicated by broken lines.

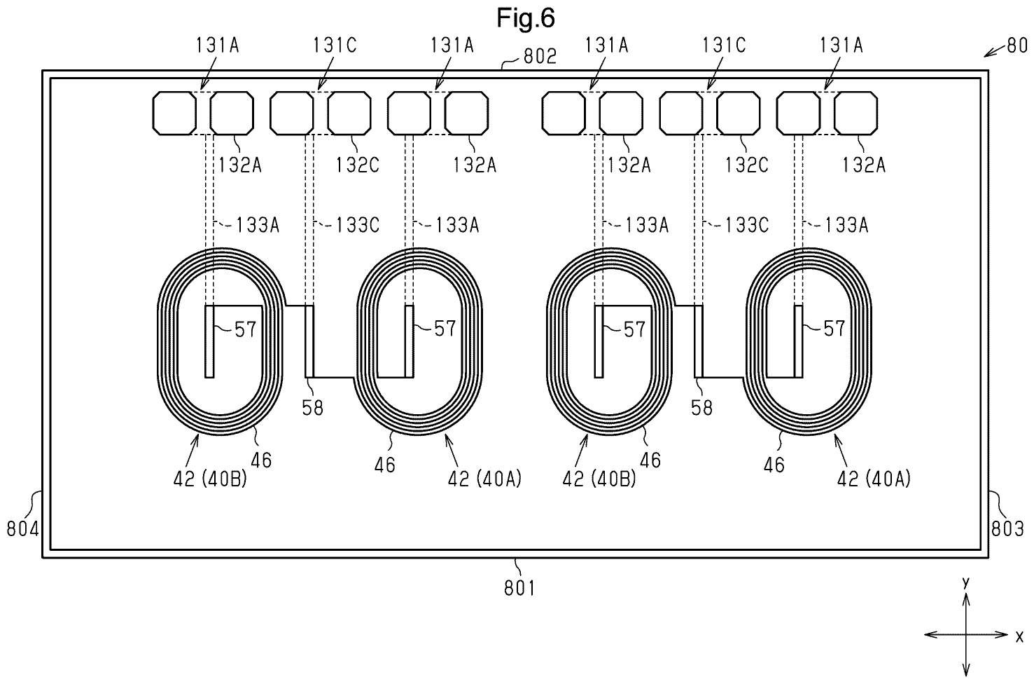

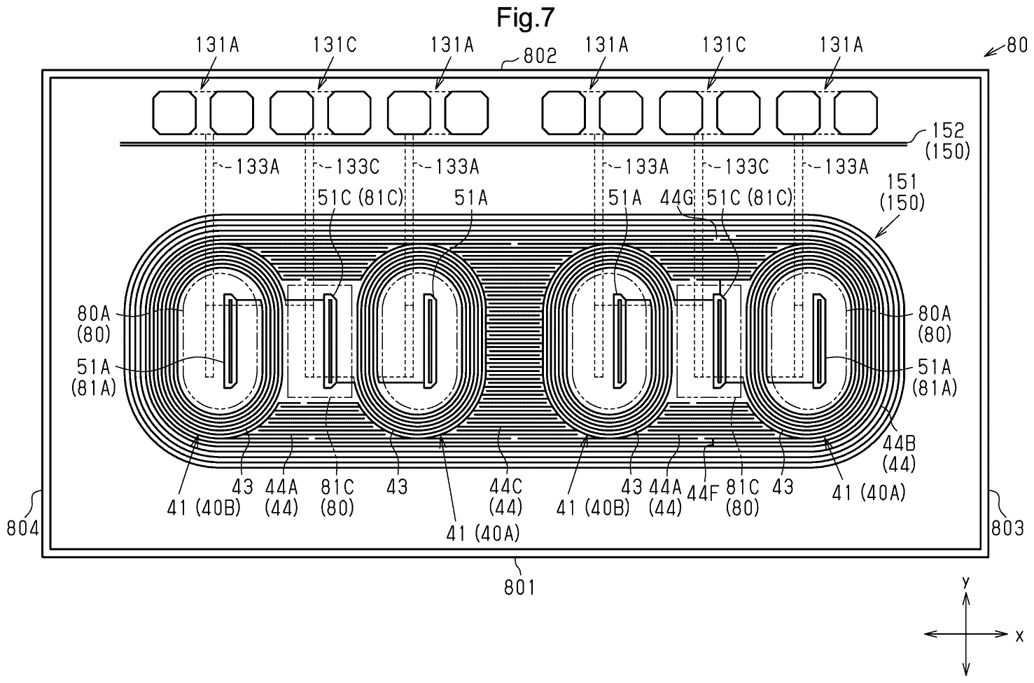

FIG. 6 is a cross-sectional view of the transformer chip 80 taken along an xy plane extending at a position in the z-direction where the second coil 42 is located. FIG. 6 shows the connection relationship of the second coil 42. FIG. 7 is a cross-sectional view of the transformer chip 80 taken along an xy plane extending at a position in the z-direction where the first coil 41 is located. FIG. 7 shows the connection relationship of the first coil 41. FIGS. 6 and 7 do not show hatching lines to simplify illustration.

FIG. 8 is a cross-sectional view of the transformer chip 80 taken along line 8-8 shown in FIG. 5. FIG. 8 shows the cross-sectional structure of the first coil 41, the stray dummy wiring 150, and a first pad 81A. FIG. 9 is a cross-sectional view of the transformer chip 80 taken along line 9-9 shown in FIG. 5. FIG. 9 shows the cross-sectional structure of outer dummy wiring 44, the stray dummy wiring 150, a second pad 81C, and a fourth pad 82C. FIGS. 8 and 9 do not show hatching lines for some of the components to simplify illustration.

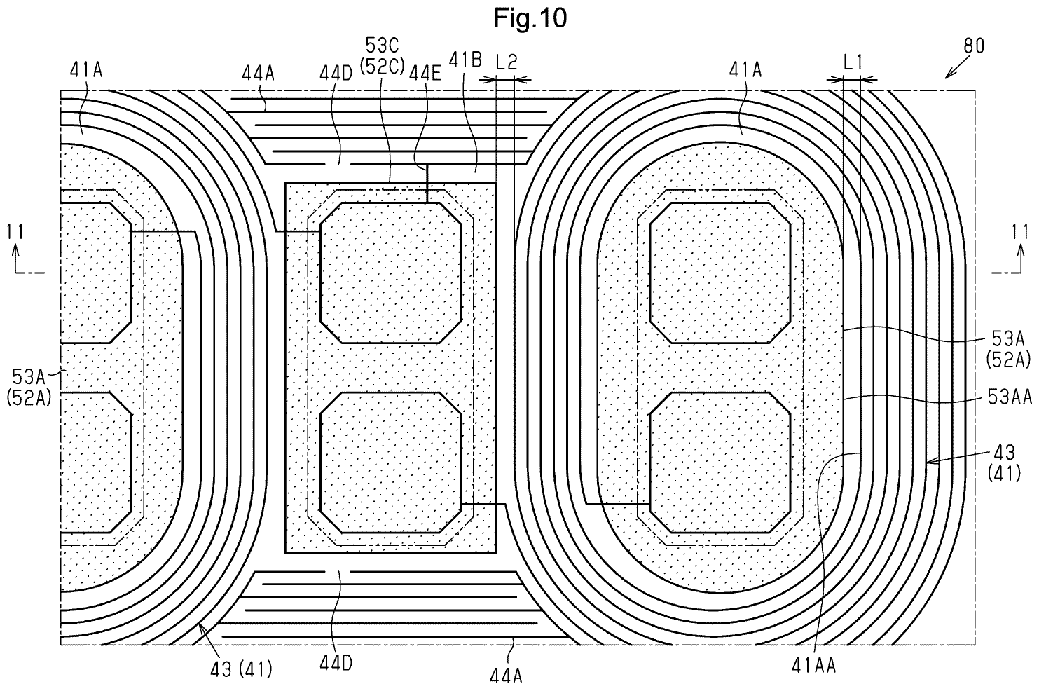

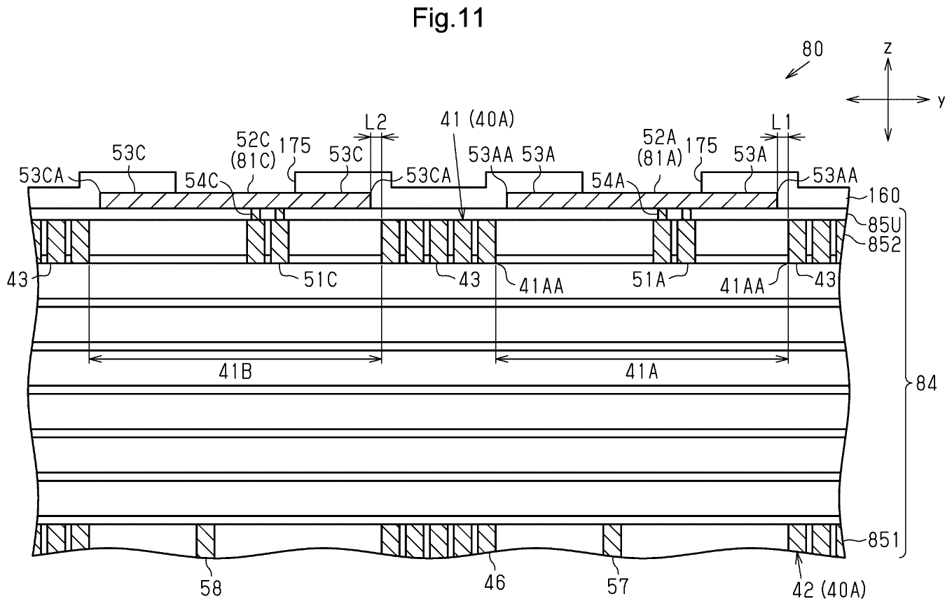

FIG. 10 is a schematic plan view enlarging part of the transformer chip 80. FIG. 10 shows the first pad 81A, the second pad 81C, the first coil 41, and the stray dummy wiring 150. FIG. 11 is a cross-sectional view of the transformer chip 80 taken along line 11-11 shown in FIG. 10. FIG. 11 shows the cross-sectional structure of the first coil 41, the first pad 81A, and the second pad 81C.

As shown in FIG. 5, the transformer chip 80 of the present embodiment includes two pairs of the transformers 40A and 40B. More specifically, the transformer chip 80 is a single semiconductor chip including two pairs of the transformers 40A and 40B. That is, the transformer chip 80 is separate from the low-voltage circuit chip 60 and the high-voltage circuit chip 70 (refer to FIG. 2).

In plan view, the transformers 40A and 40B are located near the center of the chip main surface 80s in the y-direction. In an example, the first electrode pads 81 are located at positions that do not overlap the transformers 40A and 40B in plan view. The electrode pads 81 and 82 are electrically connected to the transformers 40A and 40B.

The first electrode pads 81 include first pads 81A each located in an inner region 41A of a corresponding one of the transformers 40A and 40B, and second pads 81C each located outside the transformers 40A and 40B of a corresponding pair. The first pad 81A is electrically connected to the corresponding one of the transformers 40A and 40B. In an example, the second pad 81C is located between the transformers 40A and 40B of the corresponding pair. The second pad 81C is electrically connected to the transformers 40A and 40B of the corresponding pair. In other words, the second pad 81C is shared by the two transformers 40A and 40B.

In plan view, the first pad 81A is longer in the y-direction, which is orthogonal to the x-direction, than in the x-direction in which the first electrode pads 81 are arranged next to one another. In an example, the first pad 81A is elliptic and elongated in the y-direction. In plan view, the second pad 81C is longer in the y-direction, which is orthogonal to the x-direction, than in the x-direction in which the first electrode pads 81 are arranged next to one another. In an example, the second pad 81C is rectangular and elongated in the y-direction.

In plan view, the second electrode pads 82 include pads each aligned with a corresponding one of the two transformers 40A and the two transformers 40B in the x-direction, and pads each aligned with a portion located between the transformers 40A and 40B of a corresponding pair in the x-direction. The second electrode pads 82 are located closer to a chip side surface 802 than the transformers 40A and 40B are in the y-direction. In other words, the second electrode pads 82 are located between the transformers 40A and 40B and the chip side surface 802 in the y-direction. In plan view, the second electrode pads 82 are located closer to the low-voltage leads 102 (refer to FIG. 2) than the transformers 40A and 40B are.

In plan view, each of the second electrode pads 82 is elongated in the x-direction in which the second electrode pads 82 are arranged next to one another. In an example, the second electrode pad 82 is rectangular and elongated in the x-direction. The second electrode pads 82 include third pads 82A that correspond to the first pads 81A of the first electrode pads 81, and fourth pads 82C that correspond to the second pads 81C of the first electrode pads 81. In the transformer chip 80 of the present embodiment, each of the third pads 82A is electrically connected to a corresponding one of the transformers 40A and 40B. Each of the fourth pads 82C is electrically connected to the transformers 40A and 40B of a corresponding pair. In other words, the fourth pad 82C is shared by the two transformers 40A and 40B.

As viewed in the y-direction, the third pad 82A overlaps the corresponding one of the transformers 40A and 40B. As viewed in the y-direction, the fourth pad 82C overlaps a portion located between the transformers 40A and 40B of the corresponding pair in the x-direction. In this manner, the second electrode pads 82 (82A and 82C) are aligned at the same position in the y-direction and are spaced apart from one another in the x-direction.

The transformers 40A and 40B in one pair have the same configuration as the transformers 40A and 40B in another pair. Further, the transformers 40B have the same configuration as the transformers 40A. Thus, the structure of transformer 40A will be described in detail, and transformer 40B will not be described.

As shown in FIG. 5, the transformer chip 80 includes four chip side surfaces 801, 802, 803, and 804 that are orthogonal to both the chip main surface 80s and the chip back surface 80r. The chip side surfaces 801 to 804 extend between the chip main surface 80s and the chip back surface 80r in the z-direction. The chip side surfaces 801 and 802 form two end surfaces of the transformer chip 80 in the y-direction, and the chip side surfaces 803 and 804 form two end surfaces of the transformer chip 80 in the x-direction. In plan view, the chip side surfaces 801 and 802 form the long sides of the transformer chip 80, and the chip side surfaces 803 and 804 form the short sides of the transformer chip 80. In the present embodiment, the chip side surface 801 is located closer to the high-voltage circuit chip 70 (refer to FIG. 2) than the chip side surface 802 is, and the chip side surface 802 is located closer to the low-voltage circuit chip 60 (refer to FIG. 2) than the chip side surface 801 is.

As shown in FIGS. 5, 8, and 9, the transformer chip 80 includes a substrate 83 and an insulating layer 84 formed on the substrate 83.

The substrate 83 is formed by, for example, a semiconductor substrate. In the present embodiment, the substrate 83 is formed from a material containing silicon (Si). The Si substrate serving as the substrate 83 may be a semiconductor substrate formed from a single-crystal intrinsic semiconductor material, a p-type semiconductor substrate including an acceptor impurity, an n-type semiconductor substrate including a donor impurity, or the like.

The substrate 83 may be a semiconductor substrate, such as a wide-bandgap semiconductor, a compound semiconductor, or the like. Instead of the semiconductor substrate, the substrate 83 may be an insulating substrate formed from a material containing glass. A wide-bandgap semiconductor is a semiconductor substrate having a band gap of 2.0 eV or greater. The wide-bandgap semiconductor may include silicon carbide (SiC), gallium nitride (GaN), gallium oxide (Ga₂O₃), or the like. A compound semiconductor may be a III-V compound semiconductor. The compound semiconductor may include at least one of aluminum nitride (AlN), indium nitride (InN), GaN, and gallium arsenide (GaAs).

The substrate 83 has a substrate main surface 83s and a substrate back surface 83r at opposite sides in the z-direction. The substrate back surface 83r forms the chip back surface 80r of the transformer chip 80.

As shown in FIGS. 8 and 9, the insulating layer 84 of the present embodiment includes a plurality of insulating films 85 stacked on the substrate main surface 83s of the substrate 83 in the z-direction. That is, the z-direction corresponds to the thickness-wise direction of the insulating layer 84. Also, the z-direction corresponds to the stacking direction of the insulating films 85. The insulating layer 84 is formed on the substrate main surface 83s of the substrate 83. The insulating layer 84 has an upper surface 84s and a lower surface 84r opposite to the upper surface 84s.

The insulating films 85 include a first insulating film 85A and a second insulating film 85B formed on the first insulating film 85A. The first insulating film 85A is a thin film, such as an etching stopper layer. The first insulating film 85A is formed from a material containing silicon nitride (SiN), SiC, nitrogen-added silicon carbide (SiCN), or the like. In the present embodiment, the first insulating film 85A is formed from a material containing SiN. The second insulating film 85B is, for example, an interlayer insulating film. The second insulating film 85B is formed from a material containing silicon oxide (SiO₂). The second insulating film 85B is thicker than the first insulating film 85A. The first insulating film 85A may have a thickness of 100 nm or greater and 1000 nm or less. The second insulating film 85B may have a thickness of 1000 nm or greater and 3000 nm or less. In the present embodiment, the thickness of the first insulating film 85A is, for example, approximately 300 nm, and the thickness of the second insulating film 85B is, for example, approximately 2000 nm.

An uppermost insulating film 85U and a lowermost insulating film 85L are each formed by the second insulating film 85B. The lowermost insulating film 85L is in contact with the substrate main surface 83s of the substrate 83. In an example, both the lowermost insulating film 85L and the uppermost insulating film 85U are thinner than the other insulating films 85. The thickness of the lowermost insulating film 85L and the thickness of the uppermost insulating film 85U are both greater than or equal to the thickness of the first insulating film 85A and less than or equal to the thickness of the second insulating film 85B.

The thickness of the lowermost insulating film 85L and the thickness of the uppermost insulating film 85U may both be changed. In an example, each of the thickness of the lowermost insulating film 85L and the thickness of the uppermost insulating film 85U may be greater than the thickness of the second insulating film 85B. Furthermore, each of the thickness of the lowermost insulating film 85L and the thickness of the uppermost insulating film 85U may be greater than or equal to the thickness of the insulating film 85, which includes the first insulating film 85A and the second insulating film 85B.

### Second Coil

As shown in FIG. 6, the second coils 42 of the transformers 40A and 40B are each formed by second coil wiring 46. In plan view, the second coil wiring 46 has an elliptical spiral shape. The second coil 42 is formed from a material containing one or more selected from titanium (Ti), titanium nitride (TiN), Au, Ag, Cu, Al, and tungsten (W). Inner end wiring 57 is located at an inner side of the second coil wiring 46, and outer end wiring 58 is located at an outer side of the second coil wiring 46. One end of the second coil wiring 46 is electrically connected to the inner end wiring 57, and the other end of the second coil wiring 46 is electrically connected to the outer end wiring 58.

The inner end wiring 57 and the outer end wiring 58 are formed from a material containing one or more selected from Ti, TiN, Au, Ag, Cu, Al, and W. The outer end wiring 58 is shared by the second coils 42 of the transformers 40A and 40B of a corresponding pair. Alternatively, outer end wiring may be separately provided for each of the second coils 42 of the transformers 40A and 40B.

As shown in FIGS. 6 and 8, the inner end wiring 57 is connected to a corresponding one of the third pads 82A by an interconnection 131A. The interconnection 131A is formed from a material containing one or more selected from Ti, TiN, Au, Ag, Cu, Al, and W.

As shown in FIG. 8, the interconnection 131A includes a first interconnection portion 132A extending through the insulating films 85 in the z-direction, and a second interconnection portion 133A extending in the y-direction.

In plan view, the first interconnection portion 132A overlaps the third pad 82A and is connected to the third pad 82A. The first interconnection portion 132A extends through the insulating films 85 from the insulating film 85 that is located immediately below the uppermost insulating film 85U to the insulating film 85 that is located two layers above the lowermost insulating film 85L. The first interconnection portion 132A includes flat interconnect pieces and vias. The interconnect pieces are located at the same positions as insulating films 851 and 852 in which the coils 41 and 42 are arranged. The vias extend in the z-direction between the two interconnect pieces, between the upper interconnect piece and the third pad 82A, and between the lower interconnect piece and the second interconnection portion 133A.

The second interconnection portion 133A is located closer to the substrate 83 than the first interconnection portion 132A is. The second interconnection portion 133A is located closer to the substrate 83 than the second coil 42 is. In the present embodiment, the second interconnection portion 133A is arranged in the insulating film 85 that is located immediately above the lowermost insulating film 85L. The second interconnection portion 133A has a first end that overlaps the first interconnection portion 132A in plan view. The first end is one of two opposite ends of the second interconnection portion 133A in the y-direction that is located relatively close to the chip side surface 802 of the transformer chip 80. The second interconnection portion 133A is connected to the first interconnection portion 132A. The second interconnection portion 133A has a second end opposite to the first end. The second end does not overlap the second coil 42 of the transformer 40A in plan view. More specifically, in plan view, the second end overlaps the inner end wiring 57, which is connected to the second coil 42 of the transformer 40A. The second interconnection portion 133A includes vias 134A connecting the second interconnection portion 133A and the inner end wiring 57.

As shown in FIGS. 6 and 9, the outer end wiring 58 is electrically connected to a corresponding one of the fourth pads 82C by an interconnection 131C. The interconnection 131C is formed from a material containing one or more selected from Ti, TiN, Au, Ag, Cu, Al, and W.

As shown in FIG. 9, the interconnection 131C includes a first interconnection portion 132C extending through the insulating films 85 in the z-direction, and a second interconnection portion 133C extending in the y-direction.

The first interconnection portion 132C has the same configuration as the first interconnection portion 132A of the interconnection 131A.

In plan view, the first interconnection portion 132C overlaps the fourth pad 82C and is connected to the fourth pad 82C. The first interconnection portion 132C extends through the insulating films 85 from the insulating film 85 that is located immediately below the uppermost insulating film 85U to the insulating film 85 that is located two layers above the lowermost insulating film 85L. The first interconnection portion 132C includes flat interconnect pieces and vias. The interconnect pieces are located at the same positions as insulating films 851 and 852 in which the coils 41 and 42 are arranged. The vias extend in the z-direction between the two interconnect pieces, between the upper interconnect piece and the fourth pad 82C, and between the lower interconnect piece and the second interconnection portion 133C.

The second interconnection portion 133C is located closer to the substrate 83 than the first interconnection portion 132C is. The second interconnection portion 133C is located closer to the substrate 83 than the second coil 42 is. In the present embodiment, the second interconnection portion 133C is arranged in the insulating film 85 that is located immediately above the lowermost insulating film 85L. The second interconnection portion 133C has a first end that overlaps the first interconnection portion 132C in plan view. The first end is one of two opposite ends of the second interconnection portion 133C in the y-direction that is located relatively close to the chip side surface 802 of the transformer chip 80. The second interconnection portion 133C is connected to the first interconnection portion 132C. The second interconnection portion 133C has a second end opposite to the first end. The second end does not overlap the second coil 42 of the transformer 40A in plan view. More specifically, in plan view, the second end overlaps the outer end wiring 58, which is connected to the second coil 42 of the transformer 40A. The second interconnection portion 133C includes vias 134C connecting the second interconnection portion 133C and the outer end wiring 58. The second interconnection portion 133C of the interconnection 131C is electrically connected to the substrate 83 by vias 136 extending through the lowermost insulating film 85L. The vias 136 may be omitted.

### First Coil

As shown in FIG. 7, the first coils 41 of the transformers 40A and 40B each include first coil wiring 43. In plan view, the first coil wiring 43 has an elliptical spiral shape. The first coil 41 is formed from a material containing one or more selected from Ti, TiN, Au, Ag, Cu, Al, and W. A corresponding one of the first pads 81A is located in the inner region 41A of the first coil wiring 43. A corresponding one of the second pads 81C is located at an outer side of the first coil wiring 43. One end of the first coil wiring 43 is electrically connected to the first pad 81A, and the other end of the first coil wiring 43 is electrically connected to the second pad 81C.

The first electrode pads 81 (first pads 81A and second pads 81C) are formed from a material containing one or more selected from Ti, TiN, Au, Ag, Cu, Al, and W. The second pads 81C are each shared by the first coils 41 of the transformers 40A and 40B of a corresponding pair. Alternatively, the second pad 81C may be provided for each of the first coils 41 of the transformers 40A and 40B.

In the present embodiment, in plan view, the first coil wiring 43 has the same winding direction as the second coil wiring 46 shown in FIG. 6. Further, the first coil wiring 43 has the same number of winding turns as the second coil wiring 46.

As shown in FIG. 8, the second coil 42 and the first coil 41 of the transformer 40A (40B) face each other in the z-direction with one or more insulating films 85 interposed. In the present embodiment, the second coil 42 and the first coil 41 face each other in the z-direction with multiple insulating films 85 interposed.

The second coil 42 is formed as a conductive layer embedded in one of the insulating films 85. More specifically, the insulating film 851, in which the second coil 42 is embedded, includes a coil groove (second coil groove) 141 extending through both the first insulating film 85A and the second insulating film 85B in the z-direction. The conductive layer forming the second coil 42 is embedded in the coil groove 141 of the insulating film 851. The insulating film 851, in which the second coil 42 is embedded, is covered by the insulating films 85 located next to the insulating film 851 in the z-direction. In other words, the second coil 42 is embedded in the insulating films 85.

The first coil 41 is formed as a conductive layer embedded in one of the insulating films 85. More specifically, the insulating film 852, in which the first coil 41 is embedded, includes a coil groove (second coil groove) 142 extending through both the first insulating film 85A and the second insulating film 85B in the z-direction. The conductive layer forming the first coil 41 is embedded in the coil groove 142 of the insulating film 852. The insulating film 852, in which the first coil 41 is embedded, is covered by the insulating films 85 located next to the insulating film 852 in the z-direction. In other words, the first coil 41 is embedded in the insulating films 85.

The first coil 41 is located farther from the substrate 83 than the second coil 42 is in the z-direction. That is, the first coil 41 is located upward from the second coil 42. In other words, the second coil 42 is located closer to the substrate 83 than the first coil 41 is. In the present embodiment, the distance from the second coil 42 to the first coil 41 in the z-direction is greater than the distance from the second coil 42 to the substrate main surface 83s of the substrate 83.

As shown in FIG. 8, the first pad 81A includes base wiring 51A and pad wiring 52A electrically connected to the base wiring 51A. The base wiring 51A is located at the same position as the first coil wiring 43 in the z-direction. That is, the base wiring 51A is formed in the insulating film 852, in which the first coil 41 is embedded. The base wiring 51A is formed in a through hole extending through the insulating film 852 in the z-direction. The pad wiring 52A is formed on the uppermost insulating film 85U. The pad wiring 52A is electrically connected to the base wiring 51A by vias 54A extending through the insulating film 85U.

As shown in FIG. 9, the second pad 81C includes base wiring 51C and pad wiring 52C electrically connected to the base wiring 51C. The base wiring 51C is located at the same position as the first coil wiring 43 (refer to FIG. 8) in the z-direction. That is, the base wiring 51C is formed in the insulating film 852, in which the first coil 41 and the base wiring 51A of the first pad 81A shown in FIG. 8 are embedded. The base wiring 51C is formed in a through hole extending through the insulating film 852 in the z-direction. The pad wiring 52C is formed on the uppermost insulating film 85U. The pad wiring 52C is electrically connected to the base wiring 51C by vias 54C extending through the insulating film 85U.

As shown in FIG. 8, the third pad 82A includes base wiring 91A and pad wiring 92A electrically connected to the base wiring 91A. The base wiring 91A is located at the same position as the first coil wiring 43 and the base wiring 51A of the first pad 81A in the z-direction. That is, the base wiring 91A is formed in the insulating film 852, in which the first coil 41 is embedded. The base wiring 91A is formed in a through hole extending through the insulating film 852 in the z-direction. The pad wiring 92A is formed on the uppermost insulating film 85U. The pad wiring 92A is electrically connected to the base wiring 91A by vias 94A extending through the insulating film 85U.

As shown in FIG. 9, the fourth pad 82C includes base wiring 91C and pad wiring 92C electrically connected to the base wiring 91C. The base wiring 91C is located at the same position as the first coil wiring 43 (refer to FIG. 8) in the z-direction. That is, the base wiring 91C is formed in the insulating film 852, in which the first coil 41 shown in FIG. 8 is embedded. The base wiring 91C is formed in a through hole extending through the insulating film 852 in the z-direction. The pad wiring 92C is formed on the uppermost insulating film 85U. The pad wiring 92C is electrically connected to the base wiring 91C by vias 94C extending through the insulating film 85U.

As shown in FIGS. 5 and 7, the first coil 41 of the present embodiment includes the outer dummy wiring 44. The outer dummy wiring 44 is a wiring pattern configured to not allow current to flow to the first coil wiring 43 of the first coils 41. In the present embodiment, the outer dummy wiring 44 includes first dummy wiring 44A, second dummy wiring 44B, and third dummy wiring 44C. The first dummy wiring 44A and the second dummy wiring 44B are formed from a material containing one or more selected from Ti, TiN, Au, Ag, Cu, Al, and W.

In plan view, the first dummy wiring 44A is arranged in a region in which the second pad 81C is disposed between the first coil wiring 43 of the transformer 40A and the first coil wiring 43 of the transformer 40B in the x-direction. In plan view, the third dummy wiring 44C is disposed in a region in which the second pad 81C is not disposed between the first coil wiring 43 of the transformer 40A and the first coil wiring 43 of the transformer 40B in the x-direction.

The first dummy wiring 44A and the third dummy wiring 44C have different patterns from the first coil wiring 43. The first dummy wiring 44A and the third dummy wiring 44C are formed by multiple wiring lines. In an example, the wiring width and the wiring interval of the first dummy wiring 44A and the third dummy wiring 44C, which are formed by multiple wiring lines, are equal to the wiring width and the wiring interval of the first coil wiring 43. That is, the density (wiring density) of the first dummy wiring 44A and the third dummy wiring 44C is equal to the density (wiring density) of the first coil wiring 43. The density of the first dummy wiring 44A and the third dummy wiring 44C may differ from the density of the first coil wiring 43. The density of the first dummy wiring 44A may differ from the density of the third dummy wiring 44C.

As shown in FIG. 7, in an example, the first dummy wiring 44A and the third dummy wiring 44C each include a first slit 44D formed in the y-direction. The first dummy wiring 44A has the shape of an open loop because of the first slit 44D. The first slit 44D does not allow formation of a current loop in the first dummy wiring 44A.

The first dummy wiring 44A and the third dummy wiring 44C are electrically connected to the second pad 81C of the first electrode pad 81. In an example, the first dummy wiring 44A includes a first connection portion 44E electrically connected to the second pad 81C. The first connection portion 44E may be arranged at any position. The first dummy wiring 44A may be electrically connected to only one second pad 81C. In this manner, the first dummy wiring 44A has the same potential as the first coil 41. Accordingly, when the second reference potential at the first coil 41 changes, the voltage at the first dummy wiring 44A may become higher than the voltage at the second coil 42 in the same manner as the first coil 41.

As shown in FIG. 8, the first dummy wiring 44A (not illustrated) is located at a position aligned with the first coil 41 in the z-direction. That is, the first dummy wiring 44A is located farther from the substrate 83 than the second coil 42 is. In other words, the stray dummy wiring 150 is arranged around the coils of the transformers 40A and 40B that are located relatively close to the chip main surface 80s of the transformer chip 80.

The first dummy wiring 44A and the first coil 41 have the same voltage, thereby restricting voltage drops between the first coil 41 and the first dummy wiring 44A. This avoids concentration of the electric field at the first coil 41.

As shown in FIG. 7, in plan view, the second dummy wiring 44B surrounds the first coils 41, the first dummy wiring 44A, and the third dummy wiring 44C. The second dummy wiring 44B is electrically connected to the first dummy wiring 44A. That is, the second dummy wiring 44B is electrically connected to the first coil 41. In an example, the second dummy wiring 44B includes a second connection portion 44F electrically connected to the first dummy wiring 44A. The second connection portion 44F may be arranged at any position.

The second dummy wiring 44B is formed by multiple wiring lines surrounding the first coils 41 and the first dummy wiring 44A. In an example, the wiring width and the wiring interval of the second dummy wiring 44B, which is formed by multiple wiring lines, are equal to the wiring width and the wiring interval of the first coil wiring 43 of the first coil 41. That is, the density (wiring density) of the second dummy wiring 44B is equal to the density (wiring density) of the first coil wiring 43. The density of the second dummy wiring 44B may differ from that of the first coil wiring 43.

In an example, the second dummy wiring 44B includes a second slit 44G formed in the y-direction. The second dummy wiring 44B has the shape of an open loop because of the second slit 44G. The second slit 44G does not allow formation of a current loop in the second dummy wiring 44B.

As shown in FIG. 8, the second dummy wiring 44B is located at a position aligned with the first coil 41 in the z-direction. Although not illustrated in the drawings, the second dummy wiring 44B is located at a position aligned with the first coil 41 in the z-direction. That is, the second dummy wiring 44B is located farther from the substrate 83 than the second coil 42 is. The second dummy wiring 44B avoids concentration of the electric field around the first coil 41.

### Stray Dummy Wiring

As shown in FIG. 7, in the transformer chip 80 of the present embodiment, the stray dummy wiring 150 includes a first dummy pattern 151 and a second dummy pattern 152. The first dummy pattern 151 is formed from a material containing one or more selected from Ti, TiN, Au, Ag, Cu, Al, and W. The second dummy pattern 152 is formed from a material containing one or more selected from Ti, TiN, Au, Ag, Cu, Al, and W.

As shown in FIG. 7, in plan view, the first dummy pattern 151 surrounds the second dummy wiring 44B. The first dummy pattern 151 is electrically independent from the first coils 41. That is, the first dummy pattern 151 is not electrically connected to the first coils 41.

The first dummy pattern 151 is formed by multiple wiring lines. In an example, each of the wiring lines has the shape of a closed loop. In an example, the width of the first dummy pattern 151, which is formed by multiple wiring lines, is equal to the width of the first coil wiring 43 of the first coil 41. In an example, the wiring interval of the first dummy pattern 151 is greater than the wiring interval of the first coil wiring 43 of the first coil 41. That is, the density (wiring density) of the first dummy pattern 151 is lower than the density (wiring density) of the first coil wiring 43. The density of the first dummy pattern 151 may be equal to the density of the first coil wiring 43.

As shown in FIG. 8, the first dummy pattern 151 is located at a position aligned with the first coil 41 in the z-direction. Although not illustrated in the drawings, the first dummy pattern 151 is located at a position aligned with the first coil 41 in the z-direction. That is, the first dummy pattern 151 is located farther from the substrate 83 than the second coil 42 is. As shown in FIGS. 8 and 9, the outer dummy wiring 44 (44A and 44B) and the stray dummy wiring 150 (first dummy pattern 151) are aligned with each other in the z-direction. The first dummy pattern 151 avoids increases in the electric field intensity around the first coils 41.

As shown in FIG. 7, in plan view, the second dummy pattern 152 is arranged between the first coils 41 and the second electrode pads 82. The second dummy pattern 152 extends in the x-direction. In plan view, the second dummy pattern 152 extends along the second electrode pads 82. The second dummy pattern 152 may include multiple wiring lines. The second dummy pattern 152 is electrically independent from the first coils 41. That is, the second dummy pattern 152 is not electrically connected to the first coils 41. The second dummy pattern 152 partitions the second electrode pads 82 from the first coils 41.

As shown in FIGS. 8 and 9, the transformer chip 80 includes the passivation film 160. The passivation film 160 is formed on the upper surface 84s of the insulating layer 84. The passivation film 160 protects the insulating layer 84. The passivation film 160 is a surface protection film of the transformer chip 80. The passivation film 160 is formed from a material containing, for example, silicon oxide or silicon nitride. Examples of the material containing silicon nitride include SiN or SiCN. The passivation film 160 forms the chip main surface 80s of the transformer chip 80.

The second electrode pads 82 and the first electrode pads 81 are covered by the passivation film 160. The passivation film 160 includes open portions that expose parts of the second electrode pads 82 and parts of the first electrode pads 81. In this manner, each of the second electrode pads 82 has an exposed surface for connection with the wire W2. Also, each of the first electrode pad 81 has an exposed surface for connection with the wire W3.

The transformer chip 80 includes a resin layer 170 formed on the passivation film 160. The resin layer 170 is formed from, for example, a material containing polyimide (PI). The resin layer 170 is separated into an inner resin layer and an outer resin layer by a separation trench 173. As shown in FIG. 4, in plan view, the separation trench 173 surrounds the transformers 40A and 40B. The resin layer 170 includes first resin open portions 174, which expose the second electrode pads 82, and second resin open portions 175, which expose the first electrode pads 81.

### Details of First Pad and Second Pad

As shown in FIGS. 7, 10, and 11, in plan view, the first pad 81A is located in the inner region 41A surrounded by the first coil 41. The inner region 41A is elliptic in correspondence with the elliptical spiral shape of the first coil 41.

As shown in FIGS. 7, 8, 10, and 11, in plan view, the pad wiring 52A of the first pad 81A includes a first extension 53A extending toward the first coil 41. In other words, the first pad 81A includes the first extension 53A. The first extension 53A extends toward the first coil 41 beyond a position 5 μm inward of an inner circumferential edge 41AA of the first coil 41. In the present embodiment, the first coil 41 is formed by the first coil wiring 43. The inner circumferential edge 41AA of the first coil 41 corresponds to the inner circumferential edge of the first coil wiring 43. Preferably, a distance L1 from a distal end 53AA of the first extension 53A to the inner circumferential edge 41AA of the first coil 41 is 5 μm or less. The first extension 53A is looped. Preferably, the distance L1 from the distal end 53AA of the first extension 53A to the inner circumferential edge 41AA is 5 μm or less along the entire length of the first extension 53A.

As shown in FIGS. 7, 9, and 10, the pad wiring 52C of the second pad 81C is located at an outer side of the first coil 41 and adjacent to the first pad 81A. The second pad 81C is located in an outer region 41B surrounded by the first coil wiring 43 of the first coils 41 of the transformers 40A and 40B and the outer dummy wiring 44. In an example, in plan view, the outer region 41B is rectangular and elongated in the y-direction, which is orthogonal to the x-direction in which the first coils 41 are located next to each other.

As shown in FIGS. 9, 10, and 11, in plan view, the pad wiring 52C of the second pad 81C includes a second extension 53C extending toward the first coils 41. In other words, the second pad 81C includes the second extension 53C. The second extension 53C extends toward the first coil wiring 43 and the outer dummy wiring 44 from a position 5 μm separated from each of the first coil wiring 43 and the outer dummy wiring 44, which define the outer region 41B. In an example, the second extension 53C extends toward both the first coil wiring 43 and the outer dummy wiring 44. Preferably, a distance L2 from a distal end 53CA of the second extension 53C to each of an end portion of the first coil wiring 43 and an end portion of the outer dummy wiring 44 is 5 μm or less. The second extension 53C is looped. Preferably, the distance L2 from the distal end 53CA of the second extension 53C to each of the first coil wiring 43 and the outer dummy wiring 44 is 5 μm or less along the entire length of the second extension 53C. The distance from at least one of the first coil wiring 43 and the outer dummy wiring 44 to the second extension 53C may partially be more than 5 μm in the circumferential direction of the second extension 53C.

### Operation

The operation of the transformer chip 80 in accordance with the present embodiment will now be described.

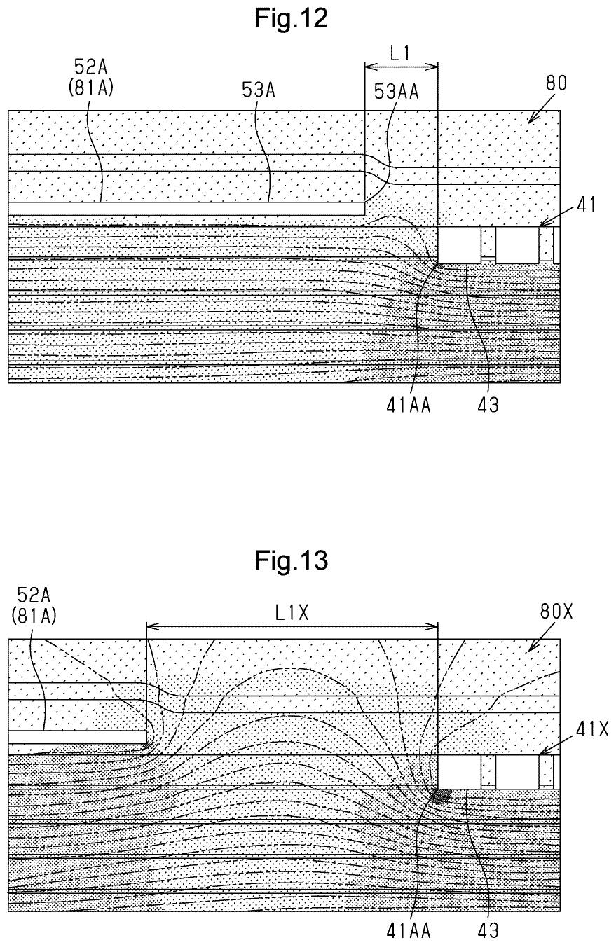

FIG. 12 shows simulated electric field distribution and simulated electric field intensity in the vicinity of the first coil 41 (first coil wiring 43) and the first pad 81A in the transformer chip 80 of the present embodiment. FIG. 13 shows simulated electric field distribution and simulated electric field intensity in the vicinity of a first coil 41X (first coil wiring 43) and the first pad 81A in a transformer chip 80X of a comparative example. In FIGS. 12 and 13, the density of dots represents the intensity of the electric field. The denser dots indicate a higher intensity of the electric field. In FIGS. 12 and 13, double-dashed lines represent equipotential lines (electric field distribution).

As shown in FIG. 13, in the transformer chip 80X of the comparative example, a distance LIX from the end of the first pad 81A to the inner circumferential edge 41AA of the first coil 41X is greater than the distance L1 in the transformer chip 80 of the present embodiment. The distance LIX in the comparative example is, for example, 20 μm. In the transformer chip 80X of the comparative example, the equipotential lines between the first coil 41X and the first pad 81A curve upward and arch above the first coil 41X. This indicates that the electric field is concentrated at the inner circumferential edge of the first coil 41X. Such concentration of the electric field may lower the dielectric breakdown voltage of the transformer chip 80X.

As shown in FIG. 12, in the transformer chip 80 of the present embodiment, the first pad 81A is located in the inner region 41A surrounded by the first coil 41 (first coil wiring 43) in plan view. The first pad 81A includes the first extension 53A extending toward the first coil 41 beyond a position 5 μm inward of the inner circumferential edge 41AA of the first coil 41. It is apparent that such a first extension 53A restricts the equipotential lines from curving upward and arching above the first coil 41. This alleviates concentration of the electric field at the inner circumferential edge 41AA of the first coil 41. That is, the first extension 53A of the first pad 81A avoids concentration of the electric field at the inner circumferential edge 41AA of the first coil 41. This improves the dielectric breakdown voltage of the transformer chip 80.

In the transformer chip 80 of the present embodiment, in plan view, the second pad 81C is located in the outer region 41B surrounded by the first coil 41 (first coil wiring 43) and the outer dummy wiring 44. The second pad 81C includes the second extension 53C extending toward the first coil 41. The second extension 53C extends toward the first coil wiring 43 and the outer dummy wiring 44 from a position 5 μm separated from each of the first coil wiring 43 and the outer dummy wiring 44, which define the outer region 41B. In the same manner as the first pad 81A, the second extension 53C of the second pad 81C restricts the equipotential lines from curving upward and arching above the first coil 41. This alleviates concentration of the electric field at the outer circumferential edge of the first coil 41, which defines the outer region 41B, and improves the dielectric breakdown voltage of the transformer chip 80.

The first extension 53A extends toward the first coil 41 beyond a position 5 μm inward of the inner circumferential edge 41AA of the first coil 41. It is apparent that such a first extension 53A restricts the equipotential lines from curving upward and arching above the first coil 41. This alleviates concentration of the electric field at the inner circumferential edge 41AA of the first coil 41. That is, the first extension 53A of the first pad 81A avoids concentration of the electric field at the inner circumferential edge 41AA of the first coil 41. This improves the dielectric breakdown voltage of the transformer chip 80.

As shown in FIGS. 5, 7, and 8, the first coil 41 of the transformer chip 80 includes the outer dummy wiring 44 surrounding the first coil wiring 43. Although not illustrated in the drawings, the equipotential lines around the transformers 40A and 40B detour around the outer dummy wiring 44 surrounding the first coil wiring 43. This alleviates concentration of the electric field at the outer circumferential edge of the first coil wiring 43.

Also, the first coil 41 of the transformer chip 80 includes the stray dummy wiring 150 (first dummy pattern 151) surrounding the outer dummy wiring 44. Although not illustrated in the drawings, the equipotential lines around the transformers 40A and 40B detour around the stray dummy wiring 150 surrounding the outer dummy wiring 44. This alleviates concentration of the electric field at the outer circumferential edge of the outer dummy wiring 44, or the outer circumferential edge of the first coil 41.

### Advantages

As described above, the present embodiment has the following advantages.

(1) In the transformer chip 80 of the present embodiment, in plan view, the first pad 81A is located in the inner region 41A surrounded by the first coil 41 (first coil wiring 43). The first pad 81A includes the first extension 53A extending toward the first coil 41 beyond a position 5 μm inward of the inner circumferential edge 41AA of the first coil 41. It is apparent that such a first extension 53A restricts the equipotential lines from curving upward and arching above the first coil 41. This alleviates concentration of the electric field at the inner circumferential edge 41AA of the first coil 41. That is, the first extension 53A of the first pad 81A avoids concentration of the electric field at the inner circumferential edge 41AA of the first coil 41. This improves the dielectric breakdown voltage of the transformer chip 80.

(2) In plan view, the second pad 81C is located in the outer region 41B surrounded by the first coil 41 (first coil wiring 43) and the outer dummy wiring 44. The second pad 81C includes the second extension 53C extending toward the first coil 41. The second extension 53C extends toward the first coil wiring 43 and the outer dummy wiring 44 from a position 5 μm separated from each of the first coil wiring 43 and the outer dummy wiring 44, which define the outer region 41B. In the same manner as the first pad 81A, the second extension 53C of the second pad 81C restricts the equipotential lines from curving upward and arching above the first coil 41. This alleviates concentration of the electric field at the outer circumferential edge of the first coil 41, and improves the dielectric breakdown voltage of the transformer chip 80.

(3) The first coil 41 of the transformer chip 80 includes the outer dummy wiring 44 surrounding the first coil wiring 43. The equipotential lines around the transformers 40A and 40B detour around the outer dummy wiring 44 surrounding the first coil wiring 43. This alleviates concentration of the electric field at the outer circumferential edge of the first coil wiring 43, and improves the dielectric breakdown voltage of the transformer chip 80.

(4) The first coil 41 of the transformer chip 80 includes the stray dummy wiring 150 (first dummy pattern 151) surrounding the outer dummy wiring 44. The equipotential lines around the transformers 40A and 40B detour around the stray dummy wiring 150 surrounding the outer dummy wiring 44. This alleviates concentration of the electric field at the outer circumferential edge of the outer dummy wiring 44, or the outer circumferential edge of the first coil 41. As a result, the dielectric breakdown voltage of the transformer chip 80 is improved.

(5) In the transformer chip 80, the transformers 40A and 40B are aligned in the x-direction. In plan view, the arrangement direction of the transformers 40A and 40B coincides with the longitudinal direction of the transformer chip 80. In plan view, the first coils 41 and the second coils 42 of the transformers 40A and 40B are each elliptic and elongated in the y-direction, in which the first electrode pads 81 are arranged next to the second electrode pads 82. In the transformer chip 80 of the present embodiment, the y-direction coincides with the widthwise direction (lateral direction) of the transformer chip 80. In this manner, the longitudinal length of the transformer chip 80 may be reduced compared to an arrangement in which the same number of transformers 40A and 40B are elliptic and elongated in the longitudinal direction of the transformer chip 80. This avoids enlargement of the transformer chip 80 in the longitudinal direction even when the number of transformers 40 is increased.

### Modified Examples

The above embodiment may be modified as described below. The above embodiment and the modified examples described below may be combined as long as there is no technical contradiction. In the modified examples described hereafter, same reference characters are given to those components that are the same as the corresponding components of the above embodiment. Such components will not be described in detail.

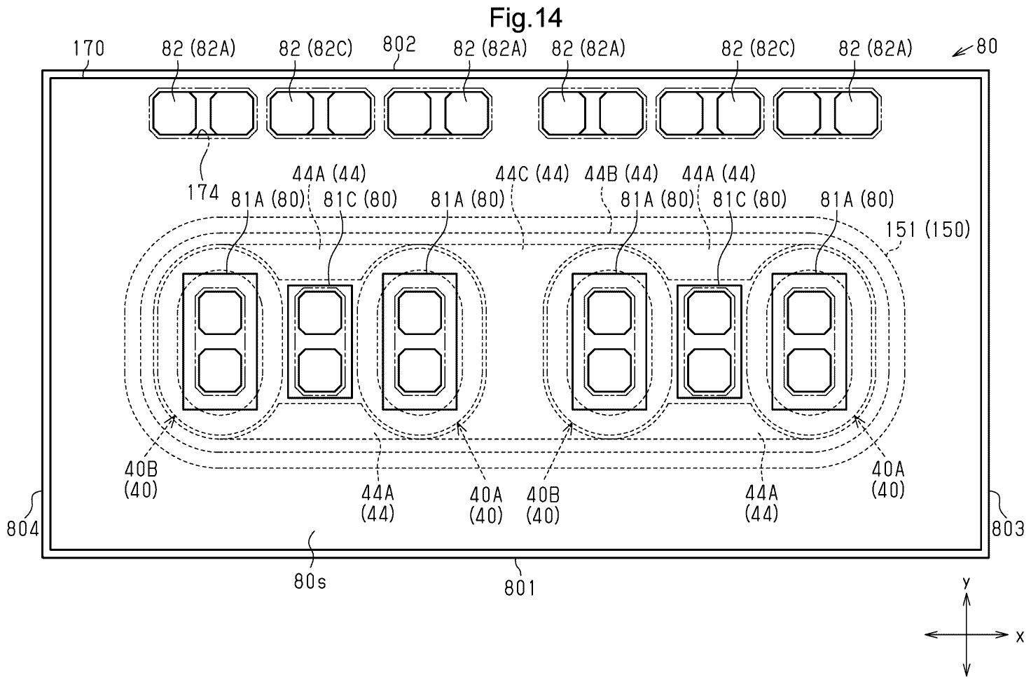

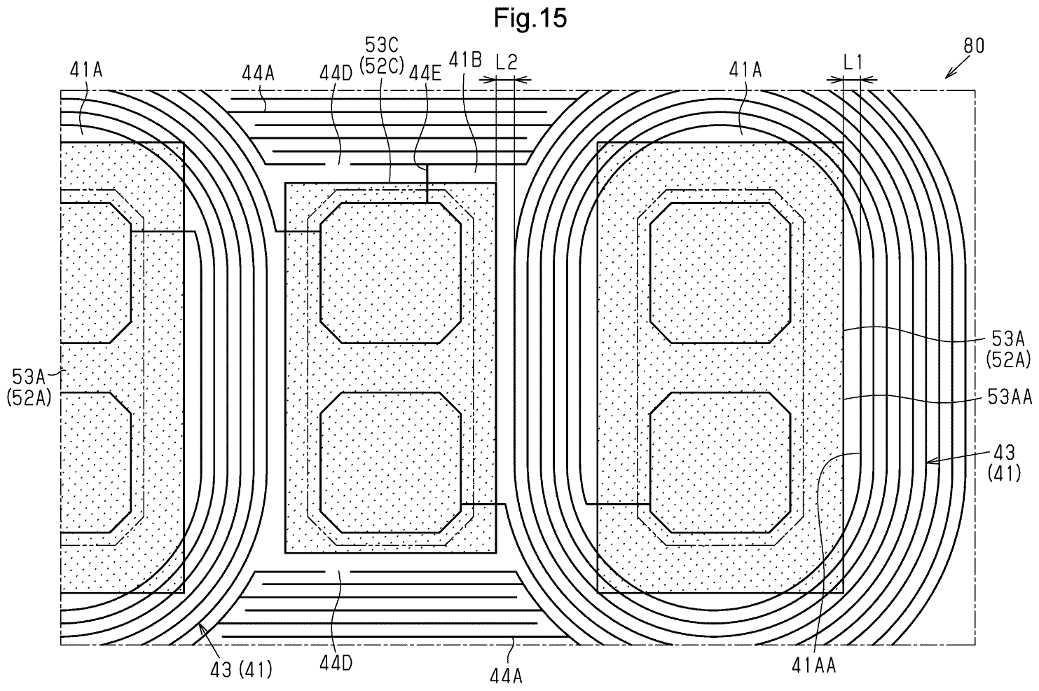

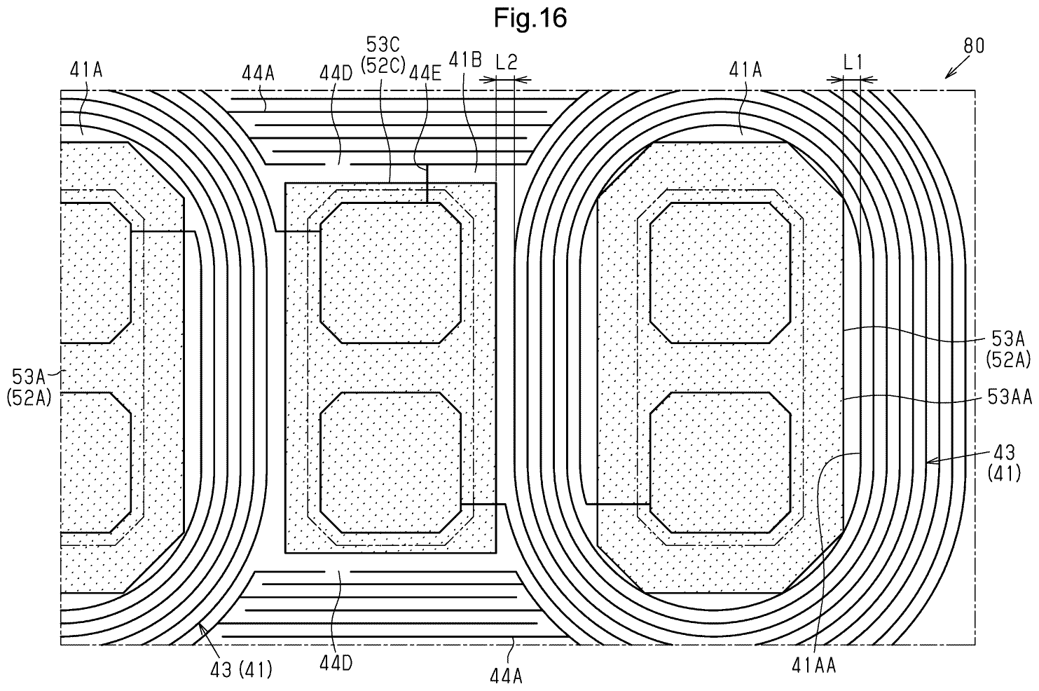

As shown in FIGS. 14 and 15, the pad wiring 52A of the first pad 81A may cover part of the first coil wiring 43. In an example, the pad wiring 52A of the first pad 81A may have a rectangular shape that is longer in the y-direction than in the x-direction. As shown in FIG. 16, the pad wiring 52A of the first pad 81A may have a polygonal shape (in FIG. 16, octagonal shape). The first pad 81A may cover the entire inner region 41A.

In the same manner, the pad wiring 52C of the second pad 81C may cover part of the first coil wiring 43. The pad wiring 52C of the second pad 81C may cover part of the outer dummy wiring 44. The pad wiring 52C of the second pad 81C may cover part of the first coil wiring 43 and part of the outer dummy wiring 44, or the entire outer region 41B. The pad wiring 52C of the second pad 81C may have any shape, such as an elliptical shape, a polygonal shape (octagonal shape), or the like, in the same manner as the first pad 81A.

The planar size of the first pad 81A (pad wiring 52A) and the planar size of the second pad 81C (pad wiring 52C) may be changed. In an example, as shown in FIGS. 14 and 15, the second pad 81C is smaller than the first pad 81A in plan view. The second pad 81C may have the same size as the first pad 81A. The second pad 81C may be larger than the first pad 81A.

The configuration of the first pad 81A may be changed.

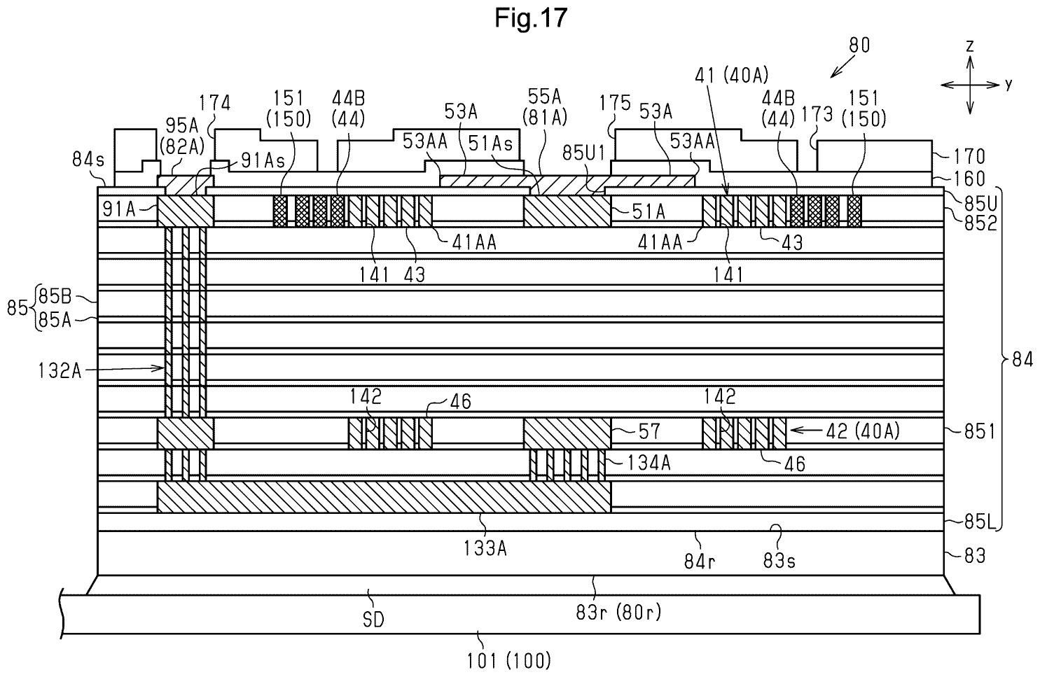

In the transformer chip 80 shown in FIG. 17, the first pad 81A includes the base wiring 51A and cap wiring 55A contacting an upper surface 51As of the base wiring 51A. The base wiring 51A is located at the same position as the first coil wiring 43 of the first coil 41 in the z-direction.

The cap wiring 55A is formed on the upper surface of the insulating film 85U. The insulating film 85U includes an opening 85U1 that exposes part of the upper surface 51As of the base wiring 51A. In the opening 85U1 of the insulating film 85U, the cap wiring 55A is in contact with the upper surface 51As of the base wiring 51A, such that the cap wiring 55A is electrically connected to the base wiring 51A. The cap wiring 55A is formed from a material containing one or more selected from Cu, Al, nickel (Ni), palladium (Pd), and W.

The cap wiring 55A extends outward beyond the base wiring 51A. The cap wiring 55A includes a first extension 56A extending toward the first coil 41. In the transformer chip 80 having the configuration described above, the first extension 56A of the cap wiring 55A alleviates concentration of the electric field at the inner circumferential edge 41AA of the first coil 41. This improves the dielectric breakdown voltage of the transformer chip 80.

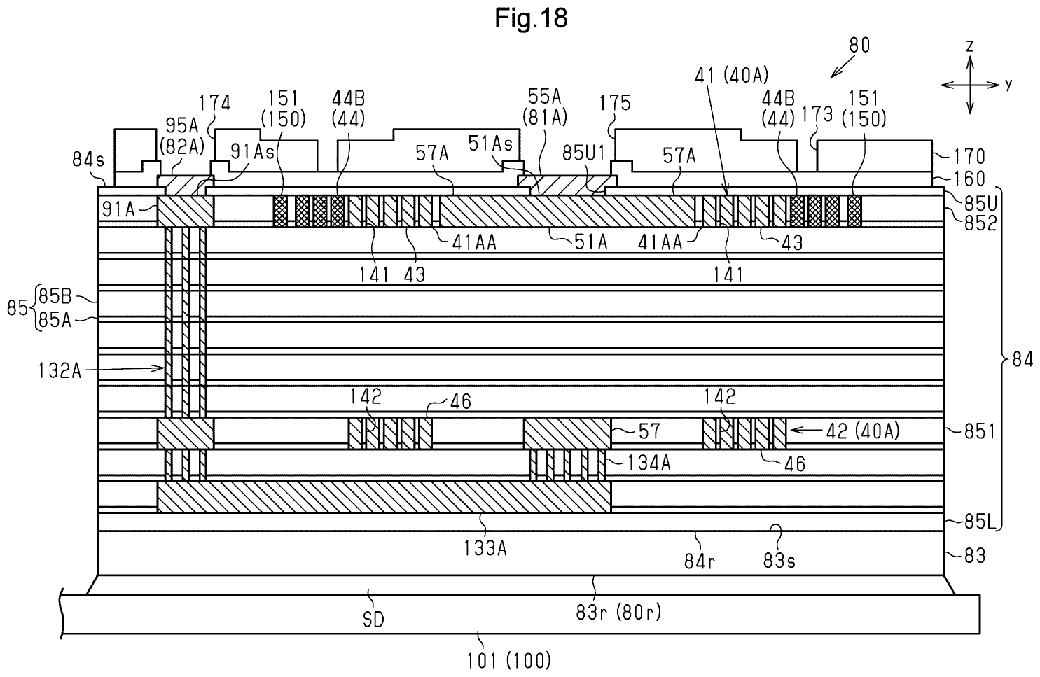

In the transformer chip 80 shown in FIG. 18, in the same manner as the transformer chip shown in FIG. 17, the first pad 81A includes the base wiring 51A and the cap wiring 55A. In this transformer chip 80, the base wiring 51A extends outward beyond the cap wiring 55A. The base wiring 51A includes a first extension 57A extending toward the first coil 41. In the transformer chip 80 having the configuration described above, the first extension 57A of the base wiring 51A alleviates concentration of the electric field at the inner circumferential edge 41AA of the first coil 41. This improves the dielectric breakdown voltage of the transformer chip 80.

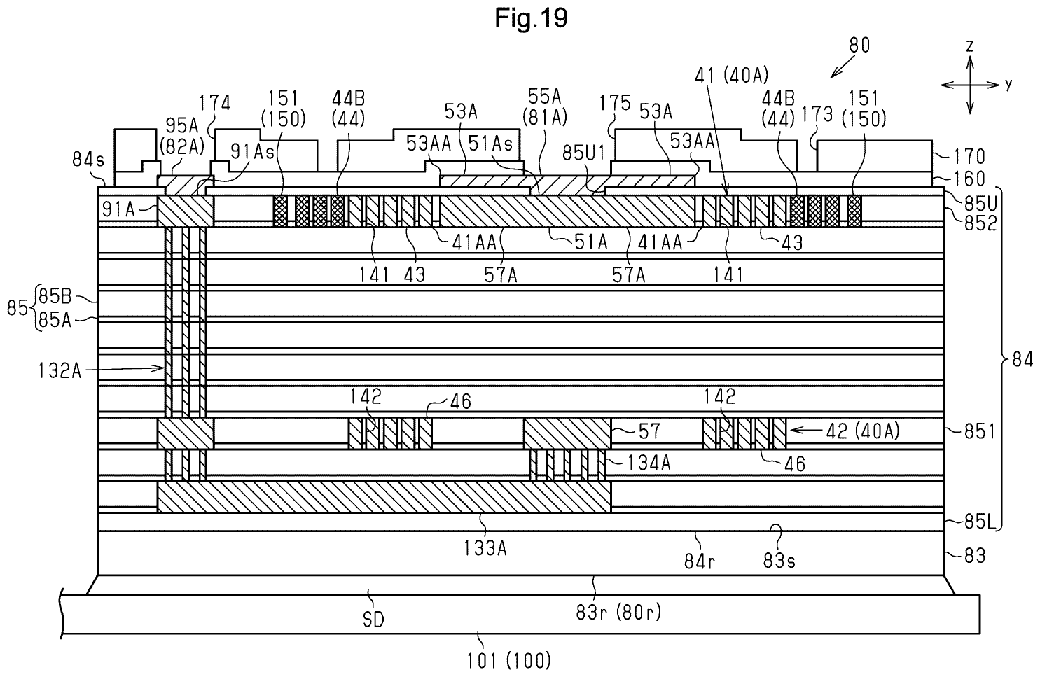

In the transformer chip 80 shown in FIG. 19, in the same manner as the transformer chip shown in FIG. 17, the first pad 81A includes the base wiring 51A and the cap wiring 55A. In the transformer chip 80, both the base wiring 51A and the cap wiring 55A extend toward the first coil 41. That is, in this transformer chip 80, the base wiring 51A includes the first extension 53A, and the cap wiring 55A includes the first extension 57A. This improves the dielectric breakdown voltage of the transformer chip 80.

In the transformer chip 80 shown in FIGS. 17, 18, and 19, in the same manner as the first pad 81A, the third pad 82A may include base wiring 51C and cap wiring contacting the upper surface of the base wiring 51C.

The second pad 81C shown in FIG. 9 may have the same configuration as the first pad 81A described above with reference to FIGS. 17 to 19. Also, the fourth pad 82C shown in FIG. 9 may have the same configuration as the third pad 82A described above with reference to FIGS. 17 to 19.

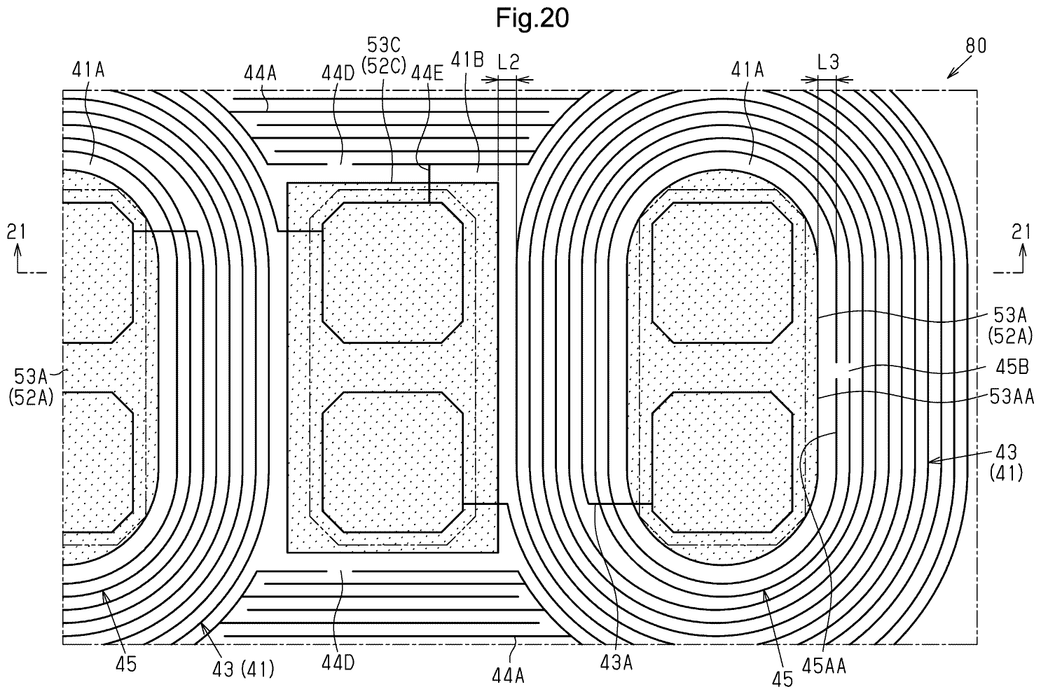

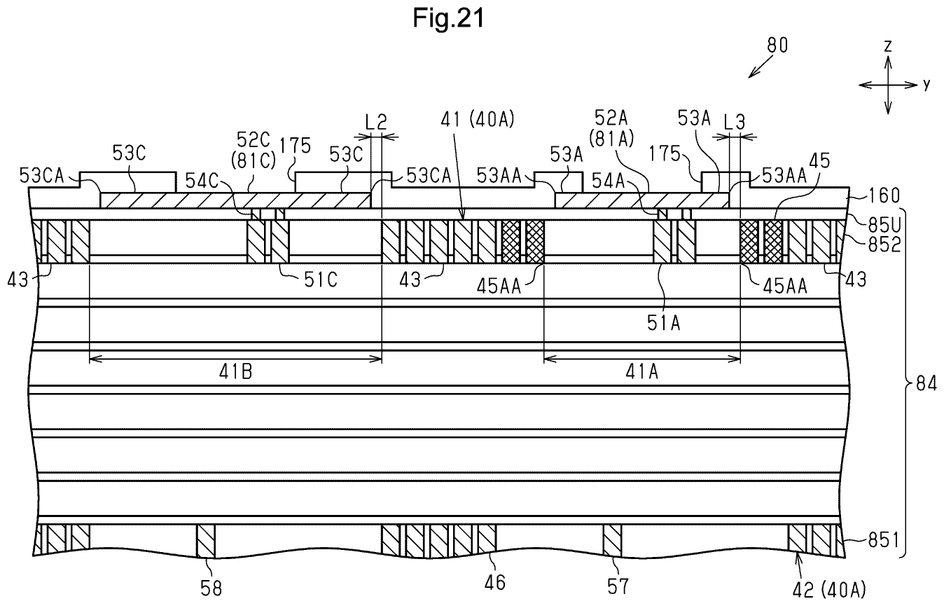

The transformer chip 80 shown in FIGS. 20 and 21 includes inner dummy wiring 45 located in the inner region 41A of the first coil 41. The inner dummy wiring 45 includes multiple wiring lines extending along the inner side of the first coil wiring 43. The inner dummy wiring 45 is electrically connected to the first coil wiring 43. The first coil wiring 43 includes a connection portion 43A electrically connected to the first pad 81A. The inner dummy wiring 45 is electrically connected to the first coil wiring 43 by the connection portion 43A. The inner dummy wiring 45 has the shape of an open loop including a slit 45B.

In this transformer chip 80, the first coil 41 includes the inner dummy wiring 45. The inner edge of the first coil 41 corresponds to an inner edge 45AA of the inner dummy wiring 45. The pad wiring 52A of the first pad 81A includes the first extension 53A extending toward the inner dummy wiring 45. A distance L3 from the distal end 53AA of the first extension 53A to the inner edge 45AA of the inner dummy wiring 45 is 5 μm or less. In the same manner as the transformer chip 80 of the above embodiment, the transformer chip 80 of the present modified example having the configuration described above alleviates concentration of the electric field at the inner circumferential edge 41AA of the first coil 41. This improves the dielectric breakdown voltage of the transformer chip 80. In the transformer chip 80, in plan view, the pad wiring 52A of the first pad 81A may cover part or all of the inner dummy wiring 45.

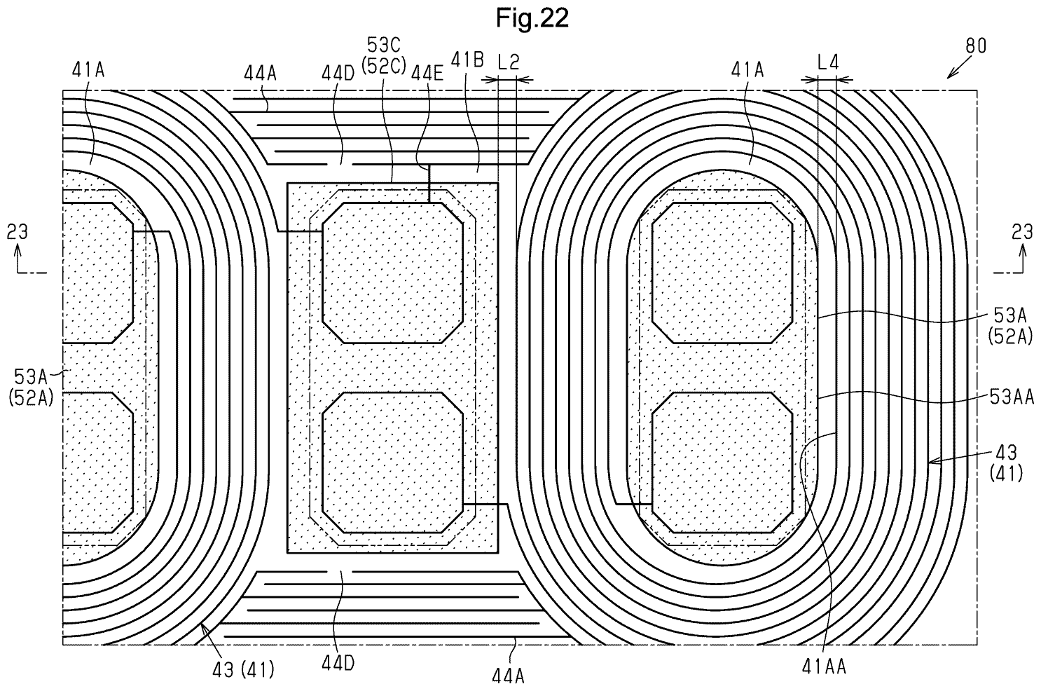

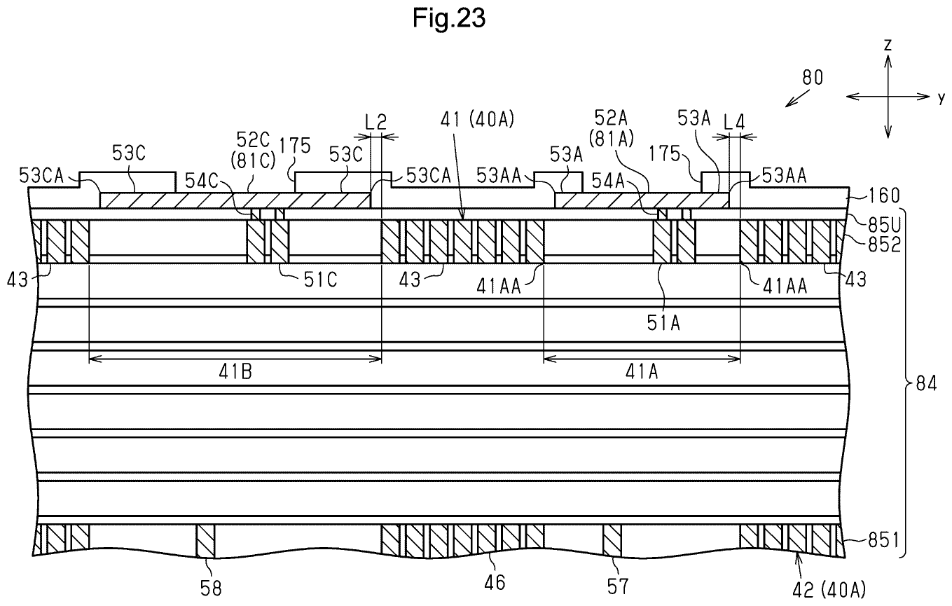

The transformer chip 80 shown in FIGS. 22 and 23 includes the first coil wiring 43 of the first coil 41, instead of the inner dummy wiring 45 of the transformer chip 80 shown in FIGS. 20 and 21. That is, the first coil wiring 43 of the first coil 41 is further wound toward the base wiring 51A of first pad 81A, increasing the number of winding turns of the first coil winding 43. In the same manner as the first coil wiring 43, the second coil wiring 46 of the second coil 42 is further wound toward the inner end wiring 57. In this transformer chip 80, the first coil wiring 43 and the second coil wiring 46 have the same number of winding turns. Alternatively, the first coil wiring 43 and the second coil wiring 46 may have different numbers of winding turns. The pad wiring 52A of the first pad 81A includes the first extension 53A extending
toward the first coil wiring 43. A distance L4 from the distal end 53AA of the first extension 53A to the inner circumferential edge 41AA of the first coil wiring 43 is 5 μm or less. In the same manner as the transformer chip 80 of the above embodiment, the transformer chip 80 having the configuration described above alleviates concentration of the electric field at the inner circumferential edge 41AA of the first coil 41. This improves the dielectric breakdown voltage of the transformer chip 80.

The number of transformers included in the transformer chip may be changed.

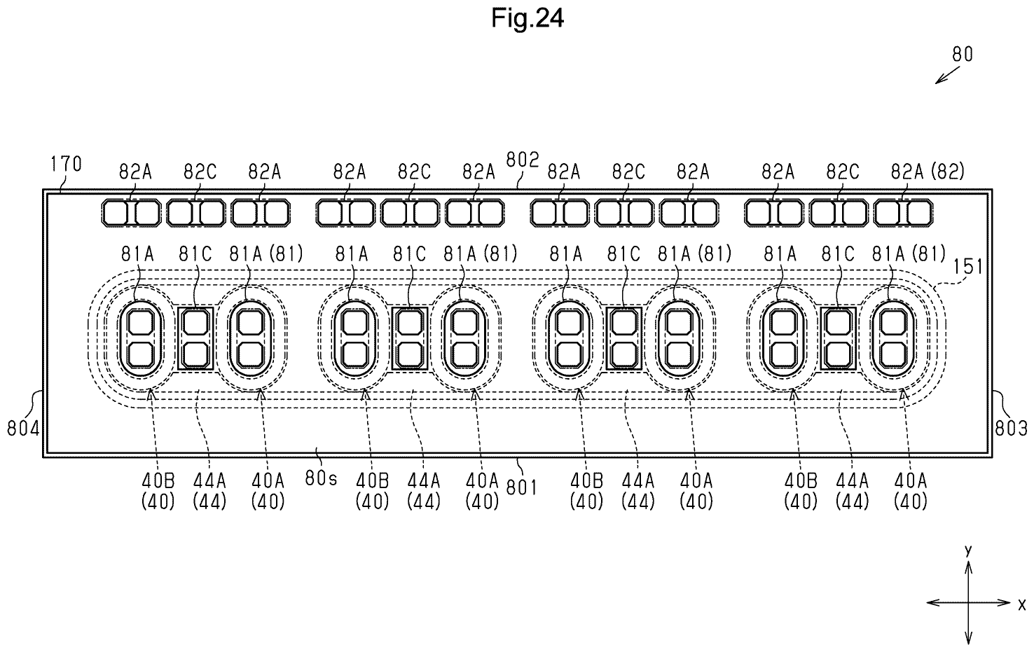

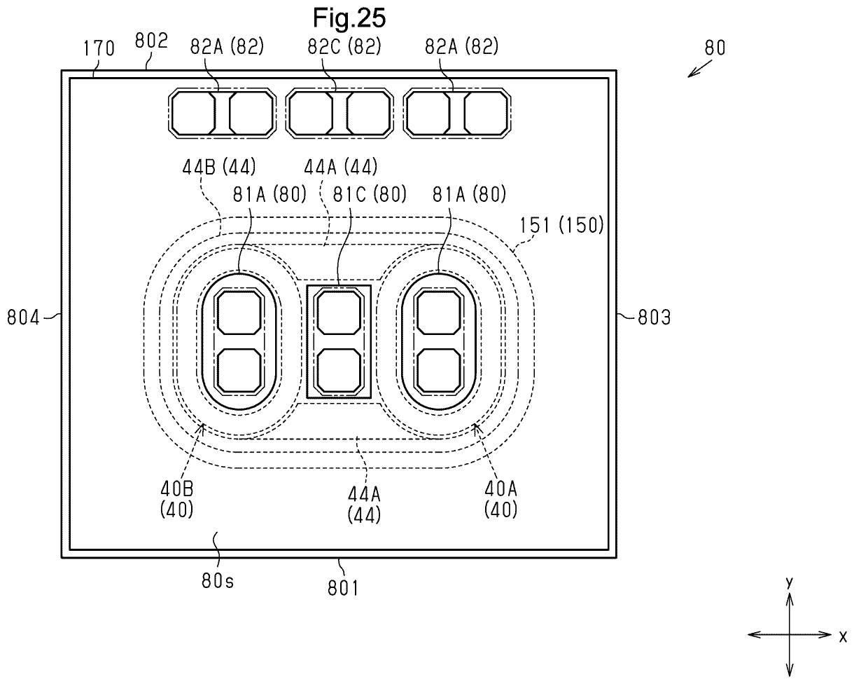

The transformer chip 80 shown in FIG. 24 includes four pairs of the transformers 40A and 40B. In such a transformer chip 80 including a large number of transformers 40A and 40B, enlargement in the longitudinal direction (x-direction) may be limited. In other words, an increased number of transformers may be included in the transformer chip 80 while limiting enlargement of the transformer chip 80 in the longitudinal direction (x-direction). This improves the dielectric breakdown voltage of the transformer chip 80.

The transformer chip 80 shown in FIG. 25 includes a single pair of the transformers 40A and 40B. This transformer chip 80 has an improved dielectric breakdown voltage.

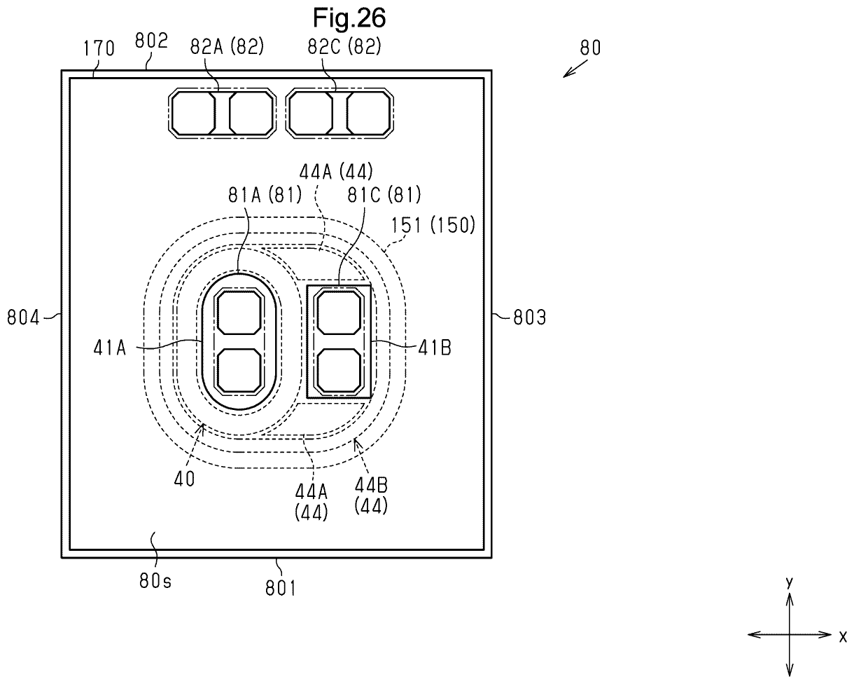

The transformer chip 80 shown in FIG. 26 includes a single transformer 40. In this transformer chip 80, the second pad 81C is arranged in the outer region 41B surrounded by the first coil wiring 43 of the first coil 41 and the first dummy wiring 44A and the second dummy wiring 44B of the outer dummy wiring 44. This transformer chip 80 has an improved dielectric breakdown voltage, in the same manner as the transformer chip 80 of the above embodiment.

The configuration of the signal transmission device may be changed.

A plurality of transformers may be connected in series to transmit signals between the low-voltage circuit 20 and the high-voltage circuit 30.

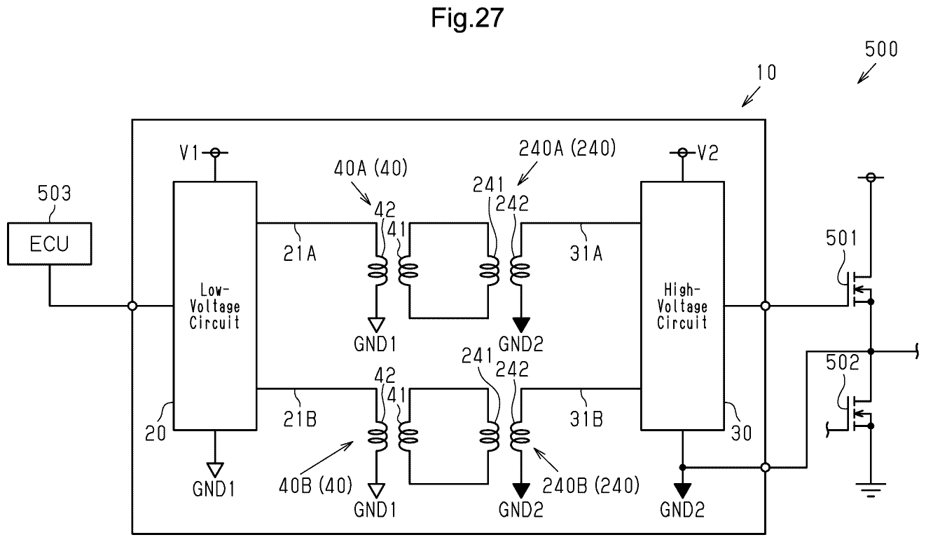

FIG. 27 shows an example of the signal transmission device 10. This signal transmission device 10 includes two transformers 40 and 240 between the low-voltage circuit 20 and the high-voltage circuit 30. In an example, the signal transmission device 10 includes two transformers 40A and 240A for transmitting a set signal, and two transformers 40B and 240B for transmitting a reset signal.

The transformers 40A and 40B each include the first coil 41 and the second coil 42. The transformers 240A and 240B each include a first coil 241 and a second coil 242. The second coils 42 of the transformers 40A and 40B are electrically connected to the low-voltage circuit 20. The first coils 41 of the transformers 40A and 40B are electrically connected to the first coils 241 of the transformers 240A and 240B. The second coils 242 of the transformers 240A and 240B are electrically connected to the high-voltage circuit 30.

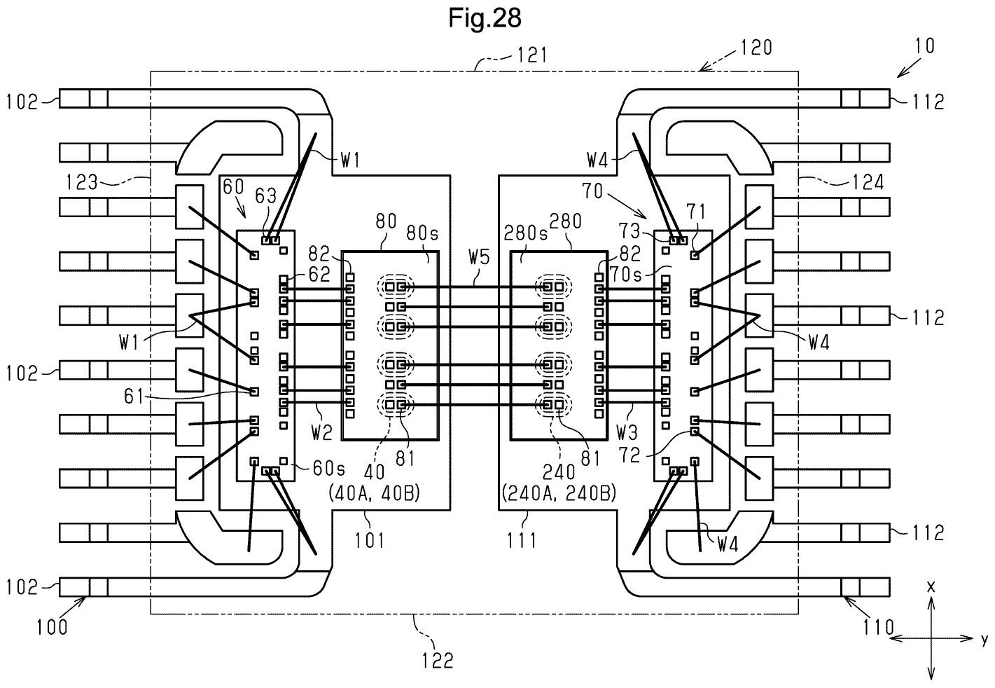

FIG. 28 shows an example of a plan view showing the internal configuration of the signal transmission device 10 shown in FIG. 27.

The signal transmission device 10 includes the low-voltage circuit chip 60, the high-voltage circuit chip 70, a first transformer chip 80, and a second transformer chip 280. The low-voltage circuit chip 60, the high-voltage circuit chip 70, the first transformer chip 80, and the second transformer chip 280 are spaced apart from one another in the y-direction. The chips 60, 70, 80, and 280 are arranged next to one another in the arrangement direction of the low-voltage die pad 101 and the high-voltage die pad 111.

In the example shown in FIG. 28, the low-voltage circuit chip 60, the first transformer chip 80, the second transformer chip 280, and the high-voltage circuit chip 70 are arranged in this order from the low-voltage leads 102 toward the high-voltage leads 112. In other words, in plan view, the first transformer chip 80 and the second transformer chip 280 are located between the low-voltage circuit chip 60 and the high-voltage circuit chip 70.

The low-voltage circuit chip 60 and the first transformer chip 80 are mounted on the low-voltage die pad 101 of the low-voltage lead frame 100. The high-voltage circuit chip 70 and the second transformer chip 280 are mounted on the high-voltage die pad 111 of the high-voltage lead frame 110. The first transformer chip 80 and the second electrode pads 82 of the second transformer chip 280 are electrically connected to the high-voltage circuit chip 70 by the wires W3. The first electrode pads 81 of the second transformer chip 280 are electrically connected to the first electrode pads 81 of the first transformer chip 80 by wires W5.

The first transformer chip 80 and the second transformer chip 280 have the same configuration as the transformer chip 80 of the above embodiment. Therefore, the first transformer chip 80 and the second transformer chip 280 each have an improved dielectric breakdown voltage. As a result, the signal transmission device 10 has a dielectric breakdown voltage that corresponds to the dielectric breakdown voltages of the first transformer chip 80 and the second transformer chip 280, which are connected in series.

In this specification, the term “on” includes the meaning of “above” in addition to the meaning of “on” unless otherwise indicated in the context. Accordingly, the phrase such as “first layer formed on second layer” may mean that the first layer is formed directly contacting the second layer in one embodiment and that the first layer is located above the second layer without contacting the second layer in another embodiment. Thus, the term “on” will also allow for a structure in which another layer is formed between the first layer and the second layer.

The Z-axis direction as referred to in this specification does not necessarily have to be the vertical direction and does not necessarily have to fully coincide with the vertical direction. Accordingly, in the structures disclosed above (e.g., structure shown in FIG. 1), upward and downward in the Z-axis direction as referred to in this specification are not limited to upward and downward in the vertical direction. For example, the x-direction may be the vertical direction. Alternatively, the y-direction may be the vertical direction.

### CLAUSES

Technical concepts that can be understood from the above embodiment and modified examples will now be described. Reference characters used in the described embodiment are added to corresponding elements in the clauses to aid understanding without any intention to impose limitations on these elements. The reference characters are given as examples to aid understanding and are not intended to limit elements to the elements denoted by the reference characters.

### Clause 1

A transformer chip, including:
an insulating layer (84) having an upper surface and a lower surface at opposite sides in a thickness-wise direction;
a first coil (41) located closer to the upper surface than to the lower surface in the insulating layer (84);
a second coil (42) facing the first coil (41) and located closer to the lower surface than to the upper surface in the insulating layer (84); and
a first pad (81A) formed on the upper surface and electrically connected to the first coil (41),
in which, as viewed in the thickness-wise direction, the first pad (81A) includes a first extension (53A) located in an inner region (41A) surrounded by the first coil (41), the first extension (53A) extending toward the first coil (41) beyond a position 5 μm inward of an inner circumferential edge of the first coil (41).

### Clause 2

The transformer chip according to clause 1, in which
the first extension (53A) is looped, and
a distance from a distal end of the first extension (53A) to the inner circumferential edge is 5 μm or less along an entire length of the first extension (53A).

### Clause 3

The transformer chip according to clause 1 or 2, in which the first pad (81A) covers an entirety of the inner region (41A).

### Clause 4

The transformer chip according to any one of clauses 1 to 3, in which
the first coil (41) includes spiral coil wiring configured to allow for current flow, and
the inner circumferential edge of the first coil (41) corresponds to an inner circumferential edge of the coil wiring.

### Clause 5

The transformer chip according to any one of clauses 1 to 3, in which
the first coil (41) includes
   spiral coil wiring (43) configured to allow for current flow, and
   inner dummy wiring (45) arranged at an inner side of the coil wiring and configured to not allow for the current flow; and
the inner circumferential edge of the first coil (41) corresponds to an inner circumferential edge of the inner dummy wiring (45).

### Clause 6

The transformer chip according to clause 5, in which the inner dummy wiring (45) has a shape of an open loop including a slit (45B).

### Clause 7

The transformer chip according to clause 5 or 6, in which a density of the inner dummy wiring (45) is equal to a density of the coil wiring.

### Clause 8

The transformer chip according to any one of clauses 4 to 7, including a second pad (81C) disposed separately from the first pad (81A) and electrically connected to the first coil (41),
in which the second pad (81C) includes a second extension (53C) located at an outer side of the first coil (41) and adjacent to the first pad (81A), the second extension (53C) extending toward the first coil (41) beyond a position 5 μm outward of an outer circumferential edge of the first coil (41) as viewed in the thickness-wise direction.

### Clause 9

The transformer chip according to clause 8, in which
the first coil (41) includes an outer dummy wiring (44) located at an outer side of the coil wiring as viewed in the thickness-wise direction, the outer dummy wiring (44) being configured to not allow for the current flow;
the second pad (81C) is located in an outer region (41B) surrounded by the coil wiring and the outer dummy wiring (44); and
the second extension (53C) extends toward both the coil wiring and the outer dummy wiring (44) from a position 5 μm separated from each of the coil wiring and the outer dummy wiring (44), which define the outer region (41B).

### Clause 10

The transformer chip according to clause 9, in which
the second extension (53C) is looped, and
a distance from a distal end of the second extension (53C) to each of the coil wiring and the outer dummy wiring (44) is 5 μm or less along an entire length of the second extension (53C).

### Clause 11

The transformer chip according to clause 9 or 10, in which the second pad (81C) covers an entirety of the outer region (41B).

### Clause 12

The transformer chip according to any one of clauses 8 to 11, in which
as viewed in the thickness-wise direction, the second pad (81C) is located next to the first pad (81A) in a first direction; and
as viewed in the thickness-wise direction, the second pad (81C) is rectangular and elongated in a second direction orthogonal to the first direction.

### Clause 13

The transformer chip according to clause 12, in which
the inner region (41A) is elliptic and elongated in the second direction, and
the first pad (81A) is elliptic and elongated in the second direction in correspondence with the inner region (41A).

### Clause 14

The transformer chip according to clause 12, in which
the inner region (41A) is elliptic and elongated in the second direction, and
the first pad (81A) is rectangular and elongated in the second direction in correspondence with the inner region (41A).

### Clause 15

The transformer chip according to any one of clauses 1 to 14, in which
the first pad (81A) includes
   base wiring (51A) located at a same position as the first coil (41) in the thickness-wise direction, and
   cap wiring (55A) contacting an upper surface of the base wiring;
the cap wiring extends outward beyond the base wiring; and
the cap wiring includes the first extension (53A).

### Clause 16

The transformer chip according to any one of clauses 1 to 14, in which
the first pad (81A) includes
   base wiring (51A) located at a same position as the first coil (41) in the thickness-wise direction, and
   cap wiring (55A) contacting an upper surface of the base wiring;
the base wiring extends outward beyond the cap wiring; and
the base wiring includes the first extension (53A).

### Clause 17

The transformer chip according to any one of clauses 1 to 14, in which
the first pad (81A) includes
   base wiring (51A) located at a same position as the first coil (41) in the thickness-wise direction, and
   cap wiring (55A) contacting an upper surface of the base wiring; and the cap wiring and the base wiring form the first extension (53A).

### Clause 18

The transformer chip according to any one of clauses 1 to 17, in which the second coil (42) has a spiral shape and overlaps the first coil (41) in the thickness-wise direction.

Exemplary descriptions are given above. In addition to the elements and methods (manufacturing processes) described to illustrate the technology of this disclosure, a person skilled in the art would recognize the potential for a wide variety of combinations and substitutions. All variations within the scope of the claims and their equivalents are included in this disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A transformer chip, comprising:
an insulating layer having an upper surface and a lower surface at opposite sides in a thickness-wise direction;
a first coil located closer to the upper surface than to the lower surface in the insulating layer;
a second coil facing the first coil and located closer to the lower surface than to the upper surface in the insulating layer; and
a first pad formed on the upper surface and electrically connected to the first coil,
wherein, as viewed in the thickness-wise direction, the first pad includes a first extension located in an inner region surrounded by the first coil, the first extension extending toward the first coil beyond a position 5 μm inward of an inner circumferential edge of the first coil.

2. The transformer chip according to claim 1, wherein
the first extension is looped, and
a distance from a distal end of the first extension to the inner circumferential edge is 5 μm or less along an entire length of the first extension.

3. The transformer chip according to claim 1, wherein the first pad covers an entirety of the inner region.

4. The transformer chip according to claim 1, wherein
the first coil includes spiral coil wiring configured to allow for current flow, and
the inner circumferential edge of the first coil corresponds to an inner circumferential edge of the coil wiring.

5. The transformer chip according to claim 1, wherein
the first coil includes
spiral coil wiring configured to allow for current flow, and
inner dummy wiring arranged at an inner side of the coil wiring and configured to not allow for the current flow; and
the inner circumferential edge of the first coil corresponds to an inner circumferential edge of the inner dummy wiring.

6. The transformer chip according to claim 5, wherein the inner dummy wiring has a shape of an open loop including a slit.

7. The transformer chip according to claim 5, wherein a density of the inner dummy wiring is equal to a density of the coil wiring.

8. The transformer chip according to claim 4, comprising a second pad disposed separately from the first pad and electrically connected to the first coil,
wherein the second pad includes a second extension located at an outer side of the first coil and adjacent to the first pad, the second extension extending toward the first coil beyond a position 5 μm outward of an outer circumferential edge of the first coil as viewed in the thickness-wise direction.

9. The transformer chip according to claim 8, wherein
the first coil includes an outer dummy wiring located at an outer side of the coil wiring as viewed in the thickness-wise direction, the outer dummy wiring being configured to not allow for the current flow;
the second pad is located in an outer region surrounded by the coil wiring and the outer dummy wiring; and
the second extension extends toward both the coil wiring and the outer dummy wiring from a position 5 μm separated from each of the coil wiring and the outer dummy wiring, which define the outer region.

10. The transformer chip according to claim 9, wherein
the second extension is looped, and
a distance from a distal end of the second extension to each of the coil wiring and the outer dummy wiring is 5 μm or less along an entire length of the second extension.

11. The transformer chip according to claim 9, wherein the second pad covers an entirety of the outer region.

12. The transformer chip according to claim 8, wherein
as viewed in the thickness-wise direction, the second pad is located next to the first pad in a first direction; and
as viewed in the thickness-wise direction, the second pad is rectangular and elongated in a second direction orthogonal to the first direction.

13. The transformer chip according to claim 12, wherein
the inner region is elliptic and elongated in the second direction, and
the first pad is elliptic and elongated in the second direction in correspondence with the inner region.

14. The transformer chip according to claim 12, wherein
the inner region is elliptic and elongated in the second direction, and
the first pad is rectangular and elongated in the second direction in correspondence with the inner region.

15. The transformer chip according to claim 1, wherein
the first pad includes
base wiring located at a same position as the first coil in the thickness-wise direction, and
cap wiring contacting an upper surface of the base wiring;
the cap wiring extends outward beyond the base wiring; and
the cap wiring includes the first extension.

16. The transformer chip according to claim 1, wherein
the first pad includes
base wiring located at a same position as the first coil in the thickness-wise direction, and
cap wiring contacting an upper surface of the base wiring;
the base wiring extends outward beyond the cap wiring; and
the base wiring includes the first extension.

17. The transformer chip according to claim 1, wherein
the first pad includes
base wiring located at a same position as the first coil in the thickness-wise direction, and
cap wiring contacting an upper surface of the base wiring; and
the cap wiring and the base wiring form the first extension.

18. The transformer chip according to claim 1, wherein the second coil has a spiral shape and overlaps the first coil in the thickness-wise direction.
